(19) United States
(12) Patent Application Publication
(10) Pub. No.: US 2011/0203636 A1
(43) Pub. Date: Aug. 25, 2011

(54) SOLAR PANELS FOR RECEIVING SCATTERED LIGHT

(76) Inventor: Brian D. Wichner, Otter Rock, OR (US)

(21) Appl. No.: 13/101,744

(22) Filed: May 5, 2011

Related U.S. Application Data
(63) Continuation-in-part of application No. 12/506,543, filed on Jul. 21, 2009, now Pat. No. 7,939,746.
(60) Provisional application No. 61/084,605, filed on Jul. 29, 2008.

(51) Int. Cl. H01L 31/042

(52) U.S. Cl. 136/244

(57) ABSTRACT

The subject matter disclosed herein relates to solar panels to generate electrical energy. In particular, solar panels configured to efficiently receive scattered light are disclosed.

### RELATED APPLICATIONS

This application is a Continuation-In-Part of U.S. application Ser. No. 12/506,543 by Brian Wichner, titled “SOLAR PANELS FOR RECEIVING SCATTERED LIGHT”, filed Jul. 21, 2009, which claims benefit of and priority to U.S. Provisional Patent Application 61/084,605 by Brian Wichner, titled “SOLAR PANELS FOR RECEIVING SCATTERED LIGHT”, filed Jul. 29, 2008, both of which are incorporated in their entirety by reference herein.

### BACKGROUND

1. Field

The subject matter disclosed herein relates to solar panels to generate electrical energy. In particular, solar panels configured to efficiently receive scattered light, such as during cloudy weather, are disclosed.

2. Information

Energy generation is of paramount importance to a developed country and its society. Petroleum-based energy sources are diminishing so that alternative sources of energy are becoming increasingly important. Among such alternative energy sources, solar energy generation holds promise to be an important candidate as a primary source of energy. Solar energy may be generated by solar panels, which include semiconductor materials configured in a solar cell to generate electrical energy and arranged in an array to sum the energy generated by individual solar cells. Among at least several reasons for this promising energy source: sunlight is virtually unlimited and free, and material for producing solar energy-generating panels is relatively inexpensive. On the other side of the coin, sunlight is available in limited quantities in many regions of the globe due to prevailing weather patterns that produce cloudy skies, which block a portion of sunlight. Also, although materials for producing solar panels are relatively inexpensive, manufacturing solar panels may be relatively expensive due to processing costs. Accordingly, current limitations on the use of energy-generating solar panels include geographical location due to weather, and the deployed number of solar panels due to expense.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIG. 1 is a schematic diagram illustrating light rays incident on a flat solar panel, according to an embodiment.

FIG. 2 is a schematic diagram illustrating a solar panel, according to an embodiment.

FIG. 3 is a schematic diagram illustrating scattered light rays incident on a solar panel, according to an embodiment.

FIG. 4 is a schematic diagram illustrating collimated light rays incident on a solar panel, according to an embodiment.

FIG. 5 is a schematic diagram illustrating a solar panel enabled to change shape, according to an embodiment.

FIGS. 6A and 6B are schematic diagrams illustrating a solar panel in a flat configuration, according to an embodiment.

FIG. 7 is a schematic diagram illustrating an array of solar panels, according to an embodiment.

FIG. 8 is a schematic diagram illustrating that light may be received on both sides of a three-dimensional solar panel.

FIG. 9A is a perspective view showing multiple 3-sided pyramidal structures that may be arranged adjacent to one another, according to an embodiment.

FIG. 9B is a perspective view showing an array of multiple 3-sided pyramidal structures, according to an embodiment.

FIG. 10A shows a top view of multiple 3-sided pyramidal structures that may be arranged adjacent to one another, according to an embodiment.

FIG. 10B shows a top view of multiple 3-sided pyramidal structures arranged adjacent to one another, according to an embodiment.

FIG. 10C shows a side view of multiple 3-sided pyramidal structures arranged adjacent to one another, according to an embodiment.

FIG. 11 shows a perspective view from above of multiple 3-sided pyramidal structures arranged adjacent to one another, according to an embodiment.

FIG. 12 shows a perspective view from below of multiple 3-sided pyramidal structures arranged adjacent to one another, according to an embodiment.

FIG. 13 shows a perspective view of two 3-sided pyramidal structures arranged adjacent to one another, according to an embodiment.

FIG. 14 shows a side view of two 3-sided pyramidal structures arranged adjacent to one another, according to an embodiment.

FIG. 15 shows a top view of two 3-sided pyramidal structures arranged adjacent to one another, according to an embodiment.

FIG. 16 shows a perspective view of pyramidal structures arranged adjacent to one another in a flow of air, according to an embodiment.

FIG. 17 shows a perspective view of multiple groups of 3-sided pyramidal structures, according to an embodiment.

FIG. 18 shows a side view of various pyramidal structures on a building, according to an embodiment.

FIG. 19 shows a perspective view of multiple groups of 3-sided pyramidal structures, according to another embodiment.

FIG. 20 shows a perspective view of 3-sided pyramidal structures arranged adjacent to one another that may rotate, according to an embodiment.

FIG. 21 shows a perspective view of 3-sided pyramidal structures arranged adjacent to one another that may include lights, according to an embodiment.

FIG. 22 shows a perspective view of 3-sided pyramidal structures arranged adjacent to one another that may include drain openings, according to an embodiment.

FIG. 23 shows a perspective view of 3-sided pyramidal structures arranged adjacent to one another that may comprise a truncated portion, according to an embodiment.

FIG. 24 shows a perspective view of 3-sided pyramidal structures arranged adjacent to one another, according to another embodiment

FIG. 25 shows a perspective view of two groups of 3-sided pyramidal structures arranged adjacent to one another, according to various embodiments.

FIGS. 26A-26D show a perspective view of a 3-sided pyramidal structure being formed, according to an embodiment.

FIGS. 27A-27D show a perspective view of multiple 3-sided pyramidal structures being formed, according to an embodiment.

FIG. 28 shows a perspective view of multiple 3-sided pyramidal structures arranged adjacent to one another and covered by a clear material, according to an embodiment.

FIG. 29 shows a perspective view of multiple 3-sided pyramidal structures arranged adjacent to one another and covered by a clear material, according to another embodiment.

FIGS. 30A-30D show a perspective view of various three dimensional solar panels at least partially enclosed in a covering, according to an embodiment.

FIG. 31 shows a perspective view of multiple three dimensional solar panel ornaments physically connected to one another, according to an embodiment.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components, and/or circuits have not been described in detail so as not to obscure claimed subject matter.

Cloudy skies are often considered to produce less solar radiation than sunny skies. But such a simple comparison may be misleading. For example, cloudy skies may produce more solar radiation in an area that would have been a shadow if the skies were sunny. In other words, more solar radiation may reach such shadow areas via scattered sunlight from clouds. Without clouds, there may be no sunlight scattering to reach the shadow area—solar radiation may only reach areas and/or surfaces that are in direct line-of-sight of the sun during sunny weather.

In an embodiment, a solar panel, which may comprise one or more individual solar panels, may be configured in a three-dimensional shape to increase its overall surface area, while keeping its footprint area, that is, the coverage area on the earth surface or a rooftop for example, constant. Though surface area may be so increased, geometrical positioning of surfaces of such a three-dimensional shape may geometrically hinder sunlight from reaching these surfaces. However, scattered sunlight may not be so hindered since such sunlight may arrive from substantially all skyward directions, whereas non-scattered sunlight may come from one direction, the sun. Cloudy skies produce such scattered sunlight.

Particular embodiments herein describe three-dimensional solar panels including pyramidal shapes, but claimed subject matter is not so limited, since any three-dimensional solar panel may provide advantages of increased surface area while keeping a fixed footprint, as described above. Herein, the term solar panels refers to a panel in a macroscopic sense, e.g., a panel that may be placed on a rooftop as suggested above, for example.

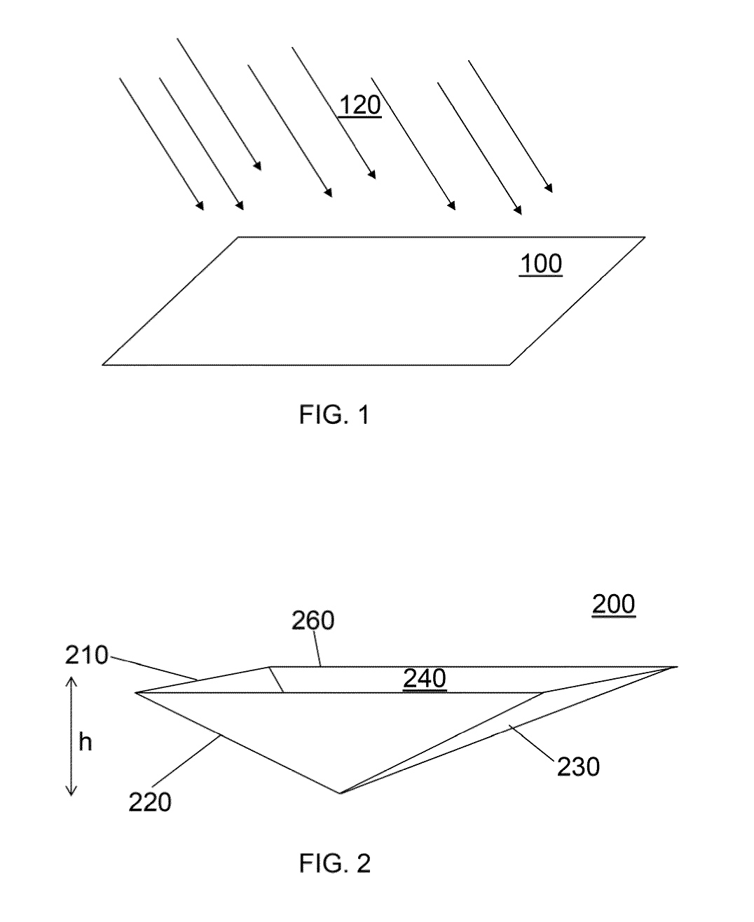

FIG. 1 is a schematic diagram illustrating light rays incident on a flat solar panel, according to an embodiment. During sunny weather, e.g., no clouds, light 120 from the sun may travel directly to a solar panel 100. A solar panel may change its angle so that sun light is incident perpendicular to the surface of the solar panel to increase solar gain efficiency.

FIG. 2 is a schematic diagram illustrating a solar panel 200, according to an embodiment. Solar panel 200 may have substantially an inverted four-sided pyramidal shape made from four individual solar panels 210, 220, 230, and 240, for example. Of course, it should be understood that such shapes need not be considered inverted since an array of such shapes may not be considered inverted, depending on which portion of the array is viewed. Such a pyramidal shape is not limited to being four-sided. Other embodiments may include three-sided, or a pyramidal shape having more than four sides.

Still other embodiments may include sides of a pyramidal shape that are truncated. Still other embodiments may include non-pyramidal shapes. For example, whereas a four-sided pyramidal shape has a square cross-section, and a three-sided pyramidal shape has a triangular cross-section, another embodiment may have a substantially circular cross-section, a substantially oval cross-section, and other shapes that may be manifested by various three-dimensional solar panel configurations. As shown in FIG. 2, individual light-collecting surface areas of individual solar panels 210, 220, 230, and 240 may face one another. In other words, the light-collecting surface of one or more such panels may be visible from the light-collecting surface of another such panel, as shown in FIG. 2, though claimed subject matter is not limited to the configuration of FIG. 2, as explained below. Herein, the term light-collecting surface refers to the surface area of a solar panel that collects light that is used to generate electricity. Such an area may also be referred to as an active region of a solar panel.

Perimeter 260 of solar panel 200 may define a surface area, which may include the footprint of solar panels 200. Such a footprint and its meaning are described above.

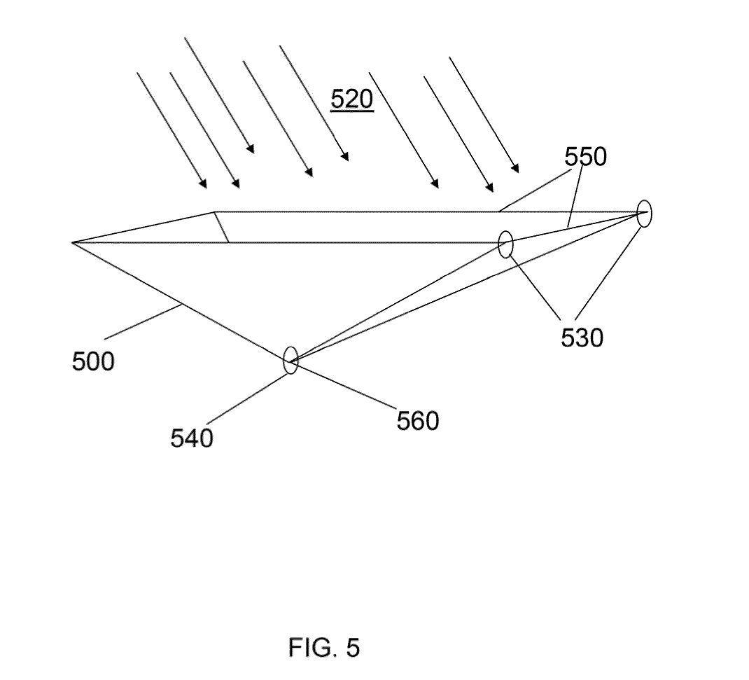

A height “h” of solar panel 200 may be determined to optimize solar gain. For example, if “h” is too large, then solar panel surface area may be large but solar radiation may not reach lower portions of solar panel 200 (e.g., near apex 560, as shown in FIG. 5). On the other hand, if “h” is too small, solar radiation may reach all portions of solar panel 200 but surface area may not be significantly large.

Solar panel 200 may be placed next to one or more similarly-shaped solar panels. For example, FIG. 7 shows an array of such panels, which will be discussed further below.

Individual solar panels 210, 220, 230, and 240 may be coupled to one another electrically and/or mechanically, or such panels may be configured so that their respective electrical connections are separate. In a particular embodiment, one or more of individual solar panels 210, 220, 230, and 240 may be connected to one another along their respective edges. In another particular embodiment, individual solar panels 210, 220, 230, and 240 may be spaced apart and/or not connected to one another. In another embodiment, solar panels 210, 220, 230, and 240 may comprise a single, or one or more solar panels. Such a single solar panel, for example, may be curved or bent to produce a pyramidal shape.

In an embodiment a “three-dimensional” solar panel 200 has an increased solar-receiving surface area compared to a flat solar panel 100 for a given perimeter area. Perimeter area, or footprint area, in this context may refer to an area of earth or roofing, for example, that either solar panel may cover. For example, in a particular embodiment, solar panel 200 may comprise a square pyramid having a height “h” and a square base with sides of length “s”. In such a case, the area of the base is s², which may be the same area as a flat solar panel 100 with a side of length “s”. But in the case of a pyramid shape, we have an additional area term, which is s(s²+4h²)^{1/2}. Accordingly, we may double, for example, the solar-gaining surface area of a solar panel by going from a flat solar panel 100 to a three-dimensional solar panel 200. Other shapes of solar panel are possible, such as a three-sided pyramid, and/or pyramids that do not necessarily have planer portions (e.g., sides. In other words, the sides of a pyramid may be curved or sagging, or faceted, for example) and so on, and claimed subject matter is not limited to a pyramidal shape. One may be concerned with an efficiency of packing in a two-dimensional space, for example, how tight can we pack our three-dimensional solar panels on a rooftop or the ground? Four and three-sided pyramids may be packed with 100% efficiency (see FIG. 7, for example), but other three-dimensional shapes may also have high packing efficiencies.

The idea of increasing solar gain is to increase surface area of solar panels while keeping the solar panels' footprint constant—this may include configuring solar panels with a third dimension, such as a depth. Pyramidal shapes compared to squares or triangles, for example, do this. And the pyramidal shapes may include angular sides to increase solar reception, compared to sides that are parallel to each other and do not pick up solar radiation as well.

In an embodiment, three-dimensional solar panels may comprise a shape similar to that of an egg carton, including the concave depression. Such an egg carton configuration is found in foam mattresses and packaging, for example. Three-dimensional solar panels may also use such a shape. Of course, this is merely an example, and claimed subject matter is not so limited.

If cloudy skies yield lower levels of solar radiation, then we can compensate by utilizing three-dimensional solar panels that have increased surface area compared to flat solar panels. Three-dimensional solar panels may not work as efficiently as flat solar panels positioned towards the sun during cloudless, sunny skies, but three-dimensional solar panels may work more efficiently than flat solar panels during cloudy skies.

Three-dimensional solar panels may actually provide an advantage to having cloudy skies compared to sunny skies: Flat solar panels generally require mechanical means to position the flat solar panels so that their surface is substantially perpendicular to the solar rays. Such positioning may be readjusted continuously throughout the day, as the sun changes position in the sky. Such mechanical means may be costly. On the other hand, three-dimensional solar panels need not be positioned to optimize their solar radiation reception because they work with cloudy days that produce scattered radiation. Accordingly, three-dimensional solar panels may not need any mechanical means to readjust their position relative to the position of the sun in the (cloudy) sky.

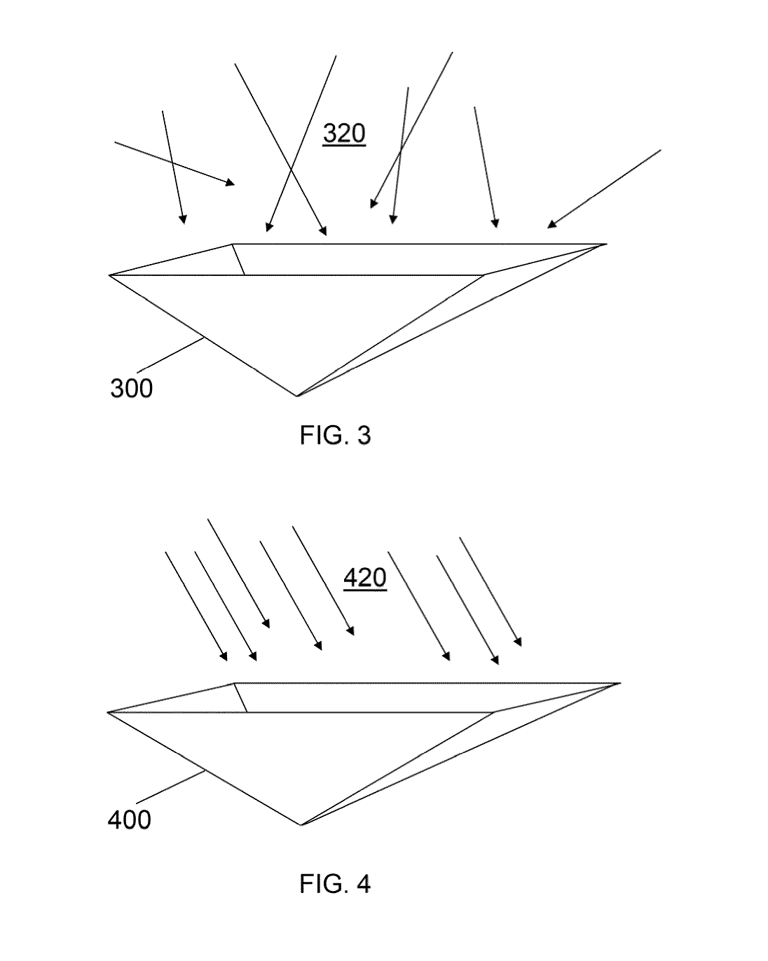

FIG. 3 is a schematic diagram illustrating scattered light rays incident on a solar panel 300, according to an embodiment. Solar panel 300 may be similar to that shown in FIG. 2, for example. During a cloudy day, for example, light rays from the sun may be scattered by the clouds. Such scattered light rays 320 may be incident on solar panel 300 from random directions. Because of the random scattered light directions, all individual solar panels 210, 220, 230, and 240 (FIG. 2) may receive substantially equal amounts of the scattered light 320. Or in another embodiment, all sides of solar panel 300 may receive substantially equal amounts of the scattered light 320. Of course, these are merely examples, and light may impinge on one individual panel more than another. Furthermore, claimed subject matter is not so limited.

FIG. 4 is a schematic diagram illustrating collimated light rays incident on a solar panel 400, according to an embodiment. On a sunny day, light from the sun may not be scattered by clouds, so that such light 420 is substantially collimated. In this case, one of the sides and/or portions of solar panel 400, or one of the individual solar panels 210, 220, 230, and 240 as in FIG. 2, may receive more light than other sides, portions, and/or panels. In an embodiment, solar panel 400 may be configured to change shape so that sides, or individual solar panels 210, 220, 230, and 240, may be positioned to receive as much light as possible. For example, individual solar panels 210, 220, 230, and 240 may change their respective position by means shown in FIG. 5, explained below.

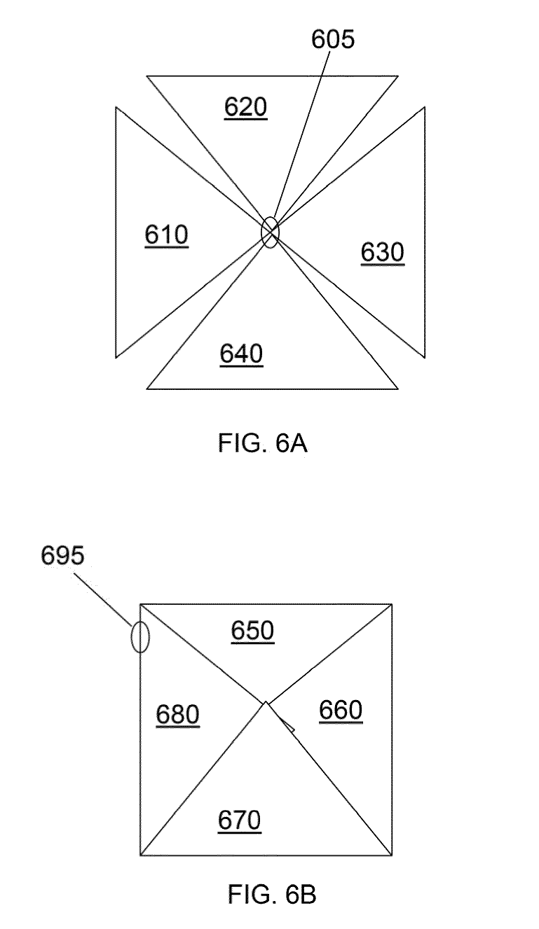

FIG. 5 is a schematic diagram illustrating a solar panel 500 enabled to change shape, according to an embodiment. Hinges or other mechanisms to enable angular position changes of individual solar panels 210, 220, 230, and 240 (FIG. 2) may be included with solar panel 500. In a particular implementation, hinges 540 may be placed at or near an apex 560 of individual solar panels 210, 220, 230, and 240 to allow the individual solar panels to rotate substantially about their apex. A piston or other mechanism (not shown) may be connected to another portion of the individual solar panels to drive a rotation about the hinge position at 560. In another particular implementation, hinges 530 may be placed at edges 550 of individual solar panels 210, 220, 230, and 240 to allow the individual solar panels to rotate about their edges. A piston or other mechanism (not shown) may be connected to another portion of the individual solar panels to drive a rotation about the hinge position at 550. FIG. 6 shows two embodiments of solar panel 500 laid flat by the action of pistons (not shown) and hinges), according to an embodiment, as explained below.

FIGS. 6A and 6B are schematic diagrams illustrating solar panels in a flat configuration, according to an embodiment. FIG. 6A may represent an embodiment of solar panel 500 with hinges 605 at the apexes of the individual solar panels 610, 620, 630, and 640. FIG. 6B may represent an embodiment of solar panel 500 with hinges 695 at the edges of the individual solar panels. In this latter embodiment, the panels may involve a sequence, wherein a first panel 650 is laid flat first (or begins an action of being laid flat first), then a second panel 660 is laid flat, then a third 680, and then a fourth 670, and so on, for example. In this way, the panels may not collide, as geometry dictates.

Solar panel 500, for example, may be laid flat during cloudless, sunny skies, when sunlight is substantially collimated. In this case, a flattened solar panel 500, as shown in either FIG. 6A or FIG. 6B, may be more efficient at capturing solar energy than the three-dimensional mode schematically illustrated in the embodiment of FIG. 5. But during cloudy days, a three-dimensional solar panel may be more efficient at capturing solar energy than a flattened mode shown in FIGS. 6A and 6B.

FIG. 7 is a schematic diagram illustrating an array 750 of solar panels 700, according to an embodiment. Such an array may be located in a field, a roof top, and so on. Perimeters of pyramidal-shaped solar panels, as described above, may be physically separated from a surface of a field or roof top on which such panels are mounted. This may be the case if an inward surface of the pyramidal-shaped solar panel is used to collect light to generate electricity. In such a case, as can be realized by viewing FIG. 7, array 750 may involve less surface contact between array 750 and a mounting surface (such as a roof top or ground) compared with mounting array 750 with pyramid perimeters contacting such a mounting surface (such as with array 750 upside down with respect to what is shown in FIG. 7). Packing of solar panels 700, which may be similar to solar panels 200 of FIG. 2, may be 100% efficient for pyramidal shapes, for example, while other shapes may provide less packing efficiency. Array 750 may include any number of solar panels, each of which need not be identical, for example.

In another embodiment, such three-dimensional solar panels, as shown in FIG. 2 for example, may be implemented on a physically unstable surface, such as on a floating vessel in the ocean. Such a vessel, or ship, may be rocked around by wave action. In such a situation, a three-dimensional solar panel may receive solar radiation relatively efficiently without involving its careful positioning and alignment, such as may be necessary for efficient operation of a flat solar panel. Accordingly, three-dimensional solar panels may work relatively well rigidly mounted to part of a sea-going vessel even while the vessel is rocked about my ocean waves. In a particular implementation, such three-dimensional solar panels, as shown in FIG. 2 for example, may be implemented on a physically unstable surface that may be a dock or other floating device in the ocean or other body of water. Such a floating surface may provide “real estate” for solar energy generation. Using land area may be difficult, so areas over water, such as lakes or oceans, may be an economical alternative. Though such a floating surface, having three-dimensional panels attached thereon, may be rocked around by wave action, three-dimensional solar panels may receive solar radiation relatively efficiently without involving their careful positioning and alignment, such as may be necessary for efficient operation of a flat solar panel. Accordingly, three-dimensional solar panels may work relatively well rigidly mounted to part of a sea-bound (or other body of water) floating platform even while the platform is rocked about by waves. Additionally, large bodies of water are often associated with cloudy skies, and three-dimensional solar panels work efficiently in such weather conditions, as explained above.

In another embodiment, such three-dimensional solar panels, as shown in FIG. 2 for example, may be implemented on a physically vertical surface, such as the side of a building, for example. During cloudy skies, scattered solar radiation is available in substantially all directions, so a vertical surface, or an area under cover from a direct line of sight to the sun's position, may receive such scattered solar radiation. Accordingly, three-dimensional solar panels are relatively efficient at receiving such scattered radiation. Such surfaces and/or areas may be economically used compared with surfaces on the ground or roofs.

In another embodiment, such three-dimensional solar panels, as shown in FIG. 2, may be implemented on ground-based vehicles, air-based vehicles, and any vehicle that changes is position relative to the sun. A weather balloon may implement such solar panels. Other vehicles may include planes, trains, and automobiles, just to list a few examples. In addition to vehicles, persons may wear clothing, for example, that have such three-dimensional solar panels mounted on such clothing. There are no size limits regarding these solar panels, so relatively small ones, perhaps configured in a matrix of such panels, may be placed on a person, an animal, and so on.

In an embodiment, such three-dimensional solar panels, as shown in FIG. 2, may be implemented inside buildings. Such interior spaces include indirect lighting from windows, skylights, and/or artificial lighting. Such indirect lighting may include scattered light, which may be received by three-dimensional solar panels, as described above. Interior space surfaces that may receive such three-dimensional solar panels may include furniture, walls, floors, structural elements, and/or any surface that may be found inside a building. Such surfaces outside a building may also receive such three-dimensional solar panels. Of course, these are merely some examples, and claimed subject matter is not so limited.

In an embodiment, such three-dimensional solar panels, as shown in FIG. 2, may be implemented on window coverings, such as curtains, blinds, and/or shades. Skylight coverings may also be considered in this regard. Such window coverings, as with other interior spaces, may include indirect lighting from windows, skylights, and/or artificial lighting. Such indirect lighting may include scattered light, which may be received by three-dimensional solar panels, as described above. In an implementation, such window coverings may be included in outdoor spaces.

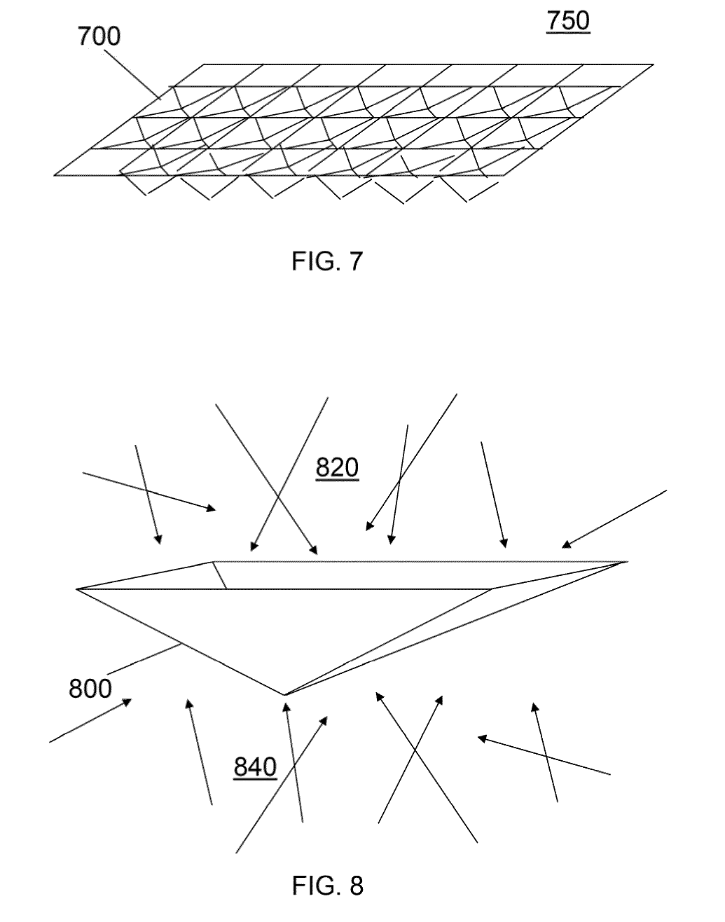

In an embodiment, such three-dimensional solar panels, as shown in FIGS. 2 and 3, may two-sided. That is, such solar panels may be configured to receive light on both opposite surfaces. Energy may be generated from both sides. For example, FIG. 8 shows that light 820 and 840 may be received on both sides of three-dimensional solar panel 800. To simplify description herein, and in terms of FIG. 8, the term “inward side” means the side of solar panel 800 that is receiving light 820, whereas the term “outward side” means the side of solar panel 800 that is receiving light 840. Such terms may also be used to describe other embodiments of a three-dimensional solar panel described above, such as for solar panels 200, 300, 400, and 500. For example, in FIG. 3, light 320 is shown incident on the inward side of solar panel 300. Accordingly, returning to FIG. 8, solar panel 800 may generate electricity by both receiving light 820 from its inward side and receiving light 840 from its outward side. Energy generation may be relatively efficient by capturing scattered light from many different directions on both sides of such a panel.

It should be understood that, although particular embodiments have been described, claimed subject matter is not limited in scope to a particular embodiment or implementation. Though the word “panel” is used, it should be understood that panel in the context of this disclosure is not limited to a plane structure, unless explicitly described as so. Further, a panel may comprise one or more individual units, be built from one or more separate structures, and/or comprise a single structure with folds and/or bends to result in a three-dimensional structure. Claimed subject matter is not so limited.

It should be understood that solar panel may refer to a material and/or a structure that is able to generate energy, particularly electricity, from light. Such light may be natural, as in sunlight, or artificial. Also, the term “solar” in “solar energy” should be understood to not be limited to that pertaining to the sun. Artificial light may apply in this context as well.

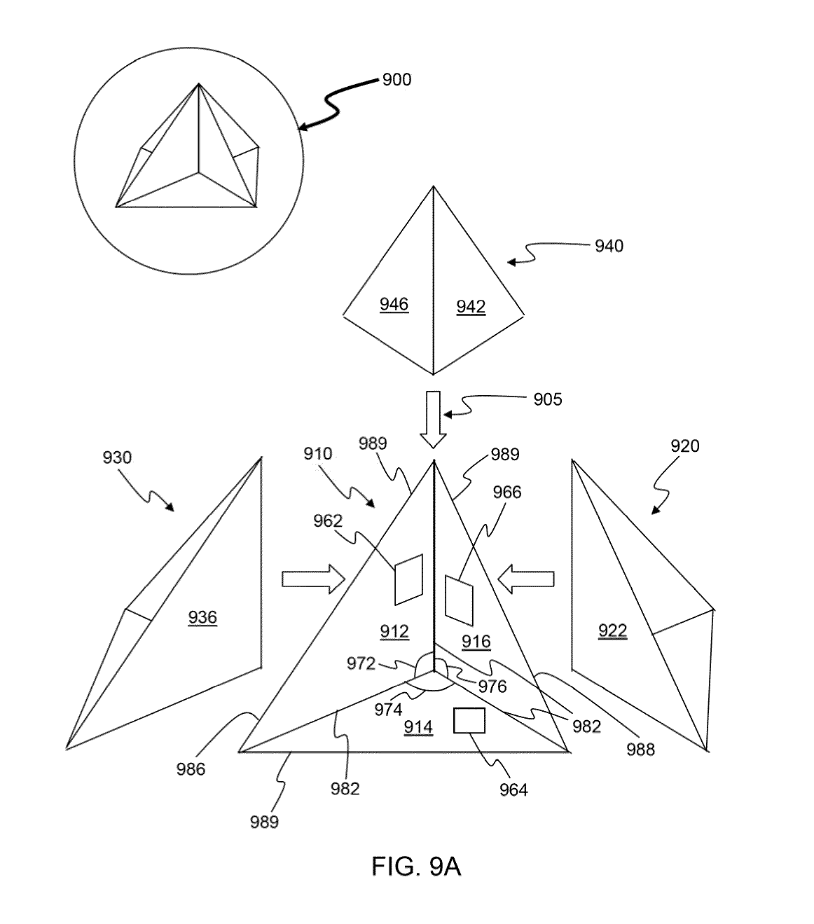

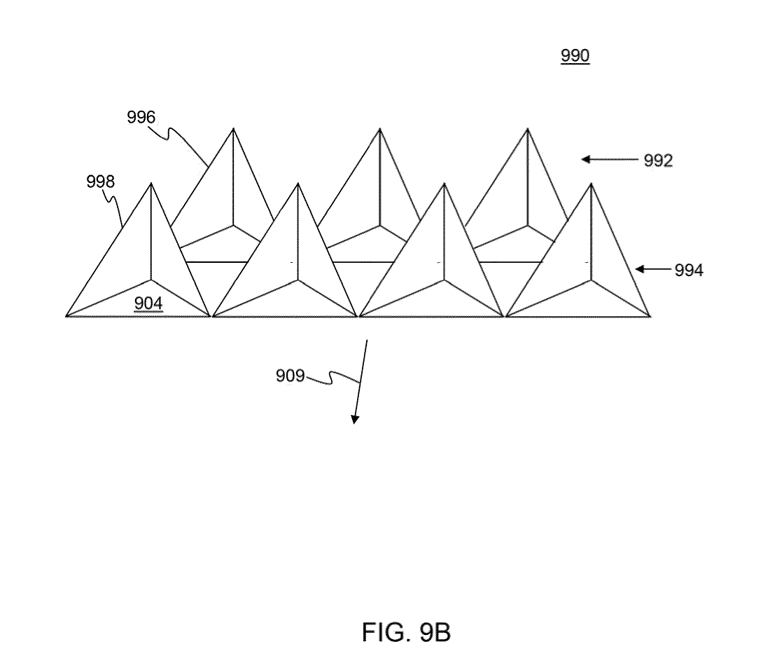

FIG. 9A is a perspective view showing multiple 3-sided pyramidal solar panels that may be arranged adjacent (e.g., back to back) to one another, according to an embodiment. In one implementation, multiple 3-sided pyramidal solar panels may be combined to form a compound pyramidal solar (CPS) panel shown in perspective in inset 900, as explained in detail below. A compound pyramid may comprise a substantially pyramidal shape or substantially pyramidal shaped outline and/or profile that comprises multiple substantially pyramidal-shaped portions. For example, a compound pyramid, shown in inset 900, may comprise a pyramidal shape that comprises multiple pyramidal-shaped portions 910, 920, 930, and/or 940. A compound pyramid may comprise a relatively large surface area to accommodate photovoltaic (PV) compared to a footprint of the compound pyramid. In addition, a compound pyramid may comprise four pyramid portions respectively facing four portions (e.g. quadrants) of the sky (or four portions of space in a room, for example). For example, a first pyramid portion may face a northeast quadrant of the sky, a second pyramid portion may face a northwest quadrant of the sky, a third pyramid portion may face a southwest quadrant of the sky, and/or a fourth pyramid portion may face a southeast quadrant of the sky. During cloudy sky conditions, for example, scattered light may be present from multiple directions. PV cells present (which may comprise a relatively large surface area) in four pyramid portions may receive scattered light from four quadrants, for example. Respective pyramid portions may receive scattered light from four quadrants that may be exclusive of one another. For example, a first pyramid portion may receive light from a first quadrant and a second pyramid portion may receive light from a second quadrant, wherein the first and second quadrants do not occupy common space. In such an implementation, for example, PV cells on different pyramid portions may receive light from respectively different portions of sky (e.g., quadrants).

3-sided pyramidal solar panels 910, 920, 930, and/or 940 may comprise a material or structure on which PV cells are placed. Solar panel 910 may comprise sides 912, 914, and/or 916. In a case where sides 912, 914, and/or 916 comprise right triangles, solar panel 910 may comprise a 3-sided pyramidal shape that may efficiently fit back to back with up to three other similar solar panels (e.g., 920, 930, and/or 940). Such a back to back configuration of three or four 3-sided pyramidal shape solar panels is shown in inset 900 (and in following figures). PV cells may be disposed on an inside surface of a 3-sided pyramidal solar panel so that sides 912, 914, and/or 916 may include PV cells of which portions 962, 964, and 966 are shown in FIG. 9A. Sides that at least partially include PV cells may be called PV surfaces. The meaning of the term “PV surfaces” may be implicit in descriptions of sides and/or surfaces of three-dimensional solar panels.

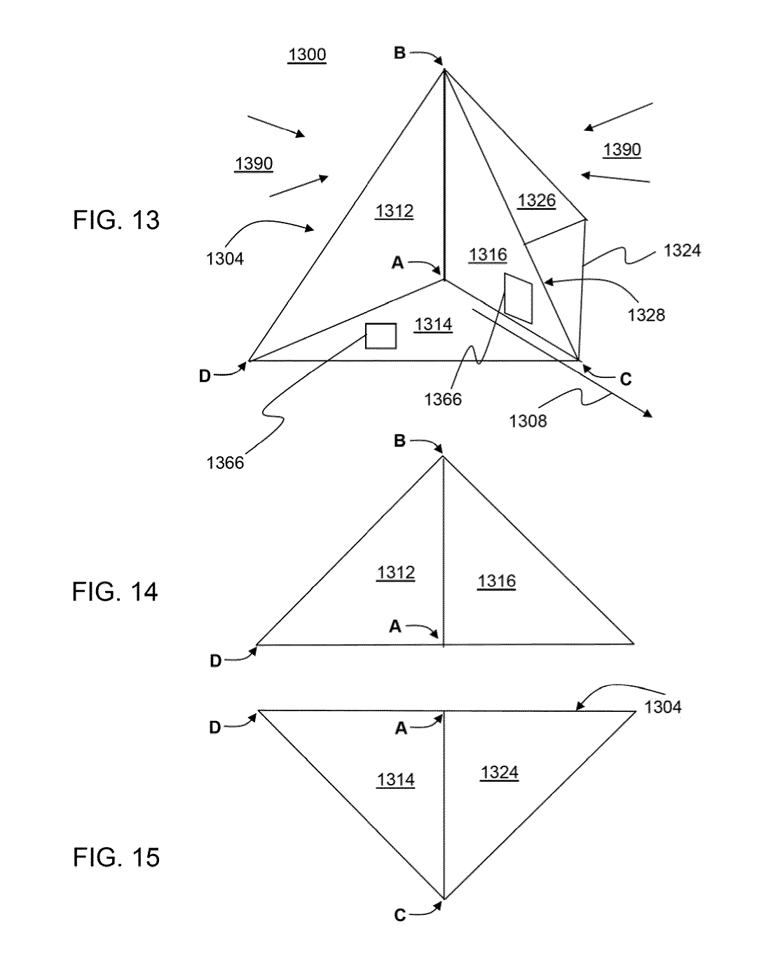

Arrows 905 show that solar panels 910, 920, 930, and/or 940 may be placed together so that, for example, solar panels 910, 920, 930, and/or 940 are back to back with one another. For example, solar panel 930 may be placed adjacent to solar panel 910 so that side 936 is side by side (e.g., and/or in contact) with side 912. Similarly, solar panel 920 may be placed adjacent to solar panel 910 so that side 922 is side by side (e.g., and/or in contact) with side 916. Similarly, solar panel 940 may be placed adjacent to solar panels 920 and/or 930 so that side 946 and side 942 are side by side (e.g., and/or in contact) with sides of solar panels 930 and 920, respectively. In one implementation (e.g., shown in FIG. 13), a solar panel configuration may include solar panels 910 and 920 and need not include solar panels 930 or 940, for example.

Inside edges 982 may comprise edges of two neighboring sides of a 3-sided pyramidal solar panel. An edge of one side need not be in contact with an edge of a neighboring side. For example, an edge of side 912 may be relatively close to an edge of side 914, but the two edges may be separated from one another. Thus, though two sides of a 3-sided pyramidal solar panel may be described as intersecting along an inside edge, the two sides need not be in contact with one another. In another implementation, however, at least portions of the two edges may be connected by a foldable hinge or flexible material. In yet another implementation, at least portions of the two edges may be rigidly connected to one another via a seam. In still another implementation, at least portions of the two edges may be rigidly connected to one another without a seam (e.g., one or more sides of a 3-sided pyramidal solar panel may be formed by a mold process).

In an implementation, solar panel 910 (or 920, 930, or 940, for example) may comprise a set of three mutually perpendicular photovoltaic (PV) surfaces comprising sides 912, 914, and 916 that form or include inside edges 982 that are substantially mutually perpendicular to one another.

In another implementation, solar panel 910 (or 920, 930, or 940, for example) may comprise a set of three PV surfaces comprising sides 912, 914, and 916 that may comprise triangles or other similar shape. For example, side 912 may include an angle 972, side 914 may include an angle 974, and side 916 may include an angle 976. In one implementation, angles 972, 974, and 976 may comprise at least approximately 90 degrees. In another implementation, angles 972 and 976 may comprise at least approximately 90 degrees and angle 974 may comprise an angle in a range from several degrees to 360 degrees. For example, if angle 974 comprises about 180 degrees, than sides 912 and 916 may be at least approximately co-planer with one another. Angle 974 may be selected based, at least in part, on how solar panel may be positioned, on placement of PV cells on the various sides (e.g., PV cells may be placed on one or both sides of any or all sides 912, 914, 916), and/or on how the solar panel may be applied. For example, if solar panel 910 is applied so that side 914 is positioned substantially vertical or steeply sloped (with respect to gravity), then the direction of the sun moving across the sky may be considered so that PV cells placed on any or all sides 912, 914, and 916 may receive desired amounts of sun light (e.g., direct and/or scattered). In another example, if solar panel 910 is applied so that side 914 is positioned substantially horizontally or relatively slightly sloped (with respect to gravity), then the direction of the sun moving across the sky may be considered so that PV cells placed on any or all sides 912, 914, and 916 may receive desired amounts of sun light (e.g., direct and/or scattered). Angle 974 (and/or 972, 976) may be selected accordingly. In another example, angle 974 may comprise about 90 degrees so that solar panel 910 may comprise a configuration that may be efficiently placed back to back with one or more other solar panels 910 (e.g., 920, 930, and/or 940). Of course, such details and recited shapes are merely examples, and claimed subject matter is not so limited.

In another implementation, solar panel 910 (or 920, 930, or 940, for example) may comprise a set of three mutually (substantially) perpendicular PV surfaces comprising sides 912, 914, and 916 that form or include outside edges 989 forming a 60-60-60 equilateral triangle.

As described above, solar panel 910 (or 920, 930, or 940, for example) may comprise sides 912, 914, and/or 916 that include PV cells. If a backside 986 of side 912 and a backside 988 of side 916 also include PV cells, then solar panel 910 may comprise an area to accommodate PV cells that is five times the area of a footprint (e.g., surface area of side 914) of solar panel 910. A plurality of solar panels similar to solar panel 910 (or 920, 930, or 940, for example) may be arranged in an array or in rows and/or columns. An example of an array 990 of solar panels 996 and 998 is shown in FIG. 9B. An array of three dimensional solar panels may be used by a utility or home owner, for example, to generate relatively large amounts of electrical power to power at least portions of a home, a community, and/or any electrical equipment, just to name a few examples. A first row 994 may include solar panels 998 and a second row 992 may include solar panels 996. Solar panels of adjacent rows may be offset from one another to minimize shadowing from one solar panel to another. To provide a particular example, array 990 may include seven solar panels 996 and 998. PV cells may be located on all sides (e.g., front and back) of the solar panels except a bottom side of base 904. If all sides of solar panels 996 and 998 comprise areas equal to one another (which is a case to which claimed subject matter and other embodiments are not so limited), then a surface area to accommodate PV cells may be five times the area of base (e.g., footprint) 904. For a numerical example, if an area of an individual side of a solar panel 996 and 998 is one square meter, then array 990 comprises a footprint area of seven square meters. A surface area to accommodate PV cells may comprise thirty-five (five sides times seven solar panels in array 990) square meters. Thus, there may be five times the amount of PV cells to generate power from scattered light on a cloudy day, for example, compared to an area of one or more footprints of solar panels. In another example, for non-scattered light, PV cells need not be located on sides facing a direction away from the sun (e.g., facing towards the north in the northern hemisphere). Thus, PV cells may be located on sides of solar panels 998 and 996 that face at least partially towards the south. Arrow 909 may indicate a southerly direction, for example. Accordingly, individual solar panels 996 and 998 may comprise three sides that include PV cells. Thus, there may be three times the amount of PV cells to generate power from direct and/or scattered light, for example, compared to an area of one or more footprints of solar panels. Of course, the number of solar panels 996 and 998 in an array 990 is not limited to any particular number.

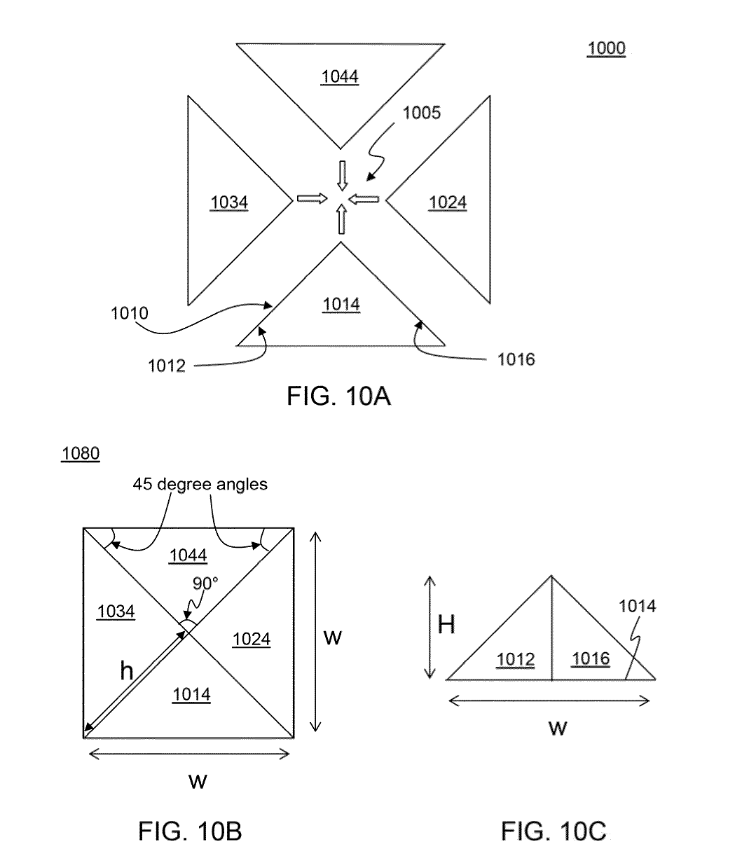

FIG. 10A shows a top view of multiple 3-sided pyramidal structures that may be arranged adjacent to one another, according to an embodiment 1000. For example, embodiment 1000 may be similar to that shown in FIG. 9A. In a top view of FIG. 10A, however, two of three sides of the 3-sided pyramidal structures are not visible as they are in the perspective view of FIG. 9A. For example, 3-sided pyramidal structure 1010 (which may be similar to 910) may include sides 1012, 1014, and/or 1016 (sides 1012 and 1016 may be projecting out of (or into) the page in FIG. 10A). Arrows 1005 indicate that any (or all) of the 3-sided pyramidal structures may be placed together, as shown in top-view FIG. 10B, for example, to form a CPS panel 1080. In such a configuration, sides 1014, 1024, 1034, and/or 1044 may comprise a base (e.g., having a footprint) of CPS panel 1080.

FIG. 10C shows a side view of CPS panel 1080. In the side view of FIG. 10C, sides 1012 and 1016 are visible, whereas side 1014 is not readily visible (as it is in FIG. 10B, for example).

Though FIGS. 9A and 10A indicate that a CPS panel (e.g., 1080) may be formed from separate multiple 3-sided pyramidal structures, claimed subject matter is not so limited. For example, a CPS panel may be formed by assembling sides in any sequence, or may be formed using a mold comprising a compound pyramidal shape, just to name a few techniques. In one implementation, a CPS panel may be fabricated by assembling multiple sides into a compound pyramidal shape (or framework, for example), such as that shown in inset 900, for example. A compound pyramidal shape may comprise a substrate upon which PV cells may be placed.

A 3-sided pyramid provides an advantage among other three dimensional solar panels in that, compared to other three-dimensional shapes having planer sides, a 3-sided pyramid has a relatively high ratio of surface area to footprint area. In embodiments that include a CPS panel, a 3-sided pyramid may comprise triangular sides having edges at 90, 45, and 45 degree angles, respectively. In other words, triangles that make up a 3-sided pyramid may comprise 90-45-45 right triangles, as indicated in FIG. 10B, for example. Right angles sides may provide an advantage in that square or rectangular PV cells may be placed on a right-angled side so that such PV cells need not be cut to fit except along the hypotenuse (e.g., the longest) side, for example. Of course, claimed subject matter is not limited to particular angles, and stated values need not be exact or precise but may be approximate. In the case of a CPS panel comprising 90-45-45 right angled sides (e.g., h=H and w=√2·h, referring to dimension labels in FIGS. 10B and 10C), the surface area of a CPS panel (e.g., to accommodate PV cells) may be three times the surface area of a base or footprint of the CPS panel. Using dimensions shown in FIGS. 10B and 10C, a base (e.g., footprint) of CPS panel 1080 may comprise an area W². For example, a flat solar panel having a footprint W² may comprise PV cells having an area W². In contrast, a CPS panel having the same footprint W² may comprise PV cells having an area 3W². In the case of a CPS panel comprising right angled triangular sides where H is greater than h, the surface area of a CPS panel (e.g., to accommodate PV cells) may be more than three times the surface area of a base or footprint of the CPS panel. For example, if H=1.5h, then a CPS panel having a footprint W² may comprise PV cells having an area 4W². For another example, if H=2h, then a CPS panel having a footprint W² may comprise PV cells having an area 5W². As a height of a CPS panel increases, there may be tradeoffs between increased surface area to accommodate PV cells and a shadowing effect on CPS panels behind one another in an array, for example, as discussed below. Of course, such details of a three-dimensional solar panel are merely examples, and claimed subject matter is not so limited.

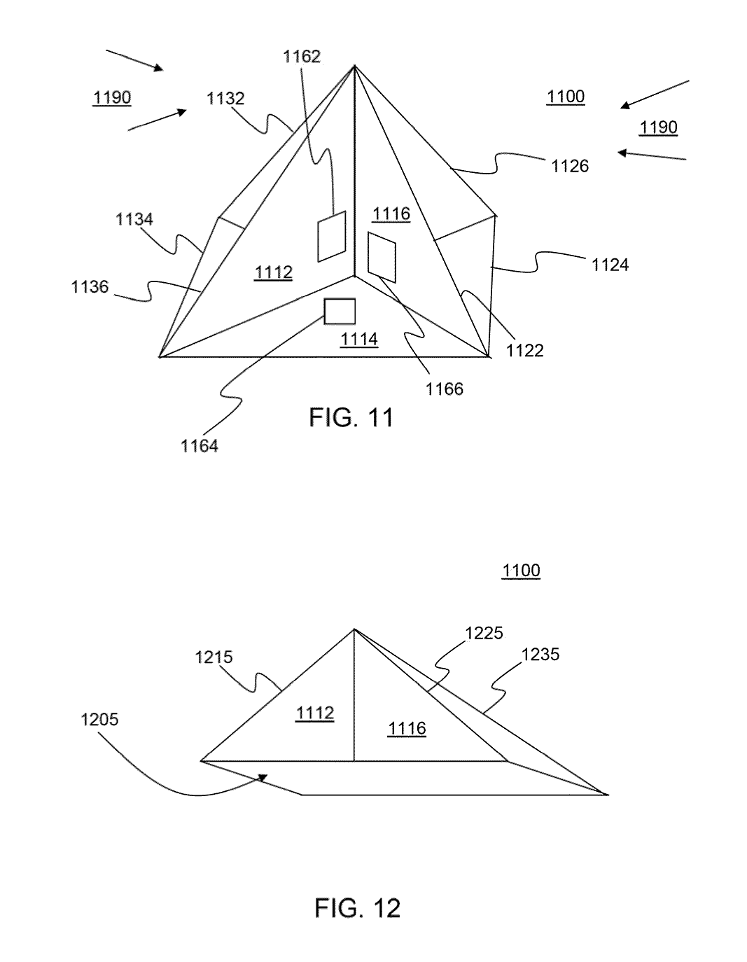

FIG. 11 shows a perspective view of a CPS panel 1100, according to an embodiment. In one implementation, CPS panel 1100 may comprise four 3-sided pyramidal structures. For example, sides 1112, 1114, and 1116 (e.g., three sides of a first quadrant) may comprise one 3-sided pyramidal structure, while sides 1122, 1124, and 1126 (e.g., three sides of a second quadrant) may comprise another 3-sided pyramidal structure. To continue, sides 1132, 1134, and 1136 (e.g., three sides of a third quadrant) may comprise yet another 3-sided pyramidal structure. A fourth 3-sided pyramidal structure may be located behind a view of CPS panel 1100 and not visible in FIG. 11, for example. 3-sided pyramidal structures may include PV cells on inside surfaces of the pyramidal structures. For example, portions 1162, 1164, and/or 1166 of PV cells are shown in FIG. 11 and may be disposed on side 1112, 1114, and/or 1116, respectively. Sides 1122, 1124, and/or 1126 may also include PV cells. Sides 1132, 1134, and/or 1136 may also include PV cells, and so on. PV cells may cover a portion or substantially all areas of sides of CPS panel 1100. PV cell portions 1162, 1164, and 1166 and their placement are merely examples, and claimed subject matter is not limited to any particular extent that CPS panel 1100 is covered with PV cells. Sides 1114, 1124, and/or 1134 (and maybe a fourth triangle portion hidden from view in FIG. 11) may comprise a base of CPS panel 1100.

FIG. 12 shows a perspective view from below of CPS panel 1100, according to an embodiment. Sides 1112 and/or 1116, among other sides not shown or labeled, may be disposed on a base 1205, In one implementation, base 1205 comprises a square shape. Side 1112 may include an edge which may comprise a ridge 1215. Side 1116 may include an edge which may comprise a ridge 1225. A third ridge 1235 is also shown in FIG. 12. Such ridges may comprise a line where a side of one 3-sided pyramidal structure joins (though physical contact need not occur) a side of another 3-sided pyramidal structure, for example.

As discussed above, CPS panel 1100 may comprise a surface area several (e.g., three) times the area of a footprint of CPS panel 1100 to accommodate PV cells positioned to receive scattered light 1190 from various directions. Thus, sides of a CPS panel may be facing a north, south, east, and/or west direction to receive scattered and/or direct light. A CPS panel may provide a further advantage in that direct sunlight (e.g., not scattered by clouds) may be received from various angles as the sun moves across the sky throughout a day. Thus, relatively costly tracking mechanisms need not be used to “track” the sun throughout a day. Also, light that is not completely absorbed by PV cells on one surface may reflect and strike a second and/or third surface of PV cells to be further absorbed. Such multiple light strikes may improve solar power generation by absorbing an increased amount of available light. For example, light (which may comprise artificial light and need not comprise sunlight) striking PV cells on surface 1116 may be partially reflected. Partially reflected light may then strike surface 1112 and be partially reflected from surface 1112. Remaining light (e.g., after striking and being partially absorbed by surfaces 1116 and 1112) may then strike surface 1114 and be partially absorbed.

FIG. 13 shows a perspective view of two 3-sided pyramidal structures arranged adjacent to one another, according to an embodiment. Described in one way, two 3-sided pyramidal structures may be combined to form a half CPS (hCPS) panel 1300. FIG. 14 shows a side view of hCPS panel 1300 and FIG. 15 shows a top view of hCPS panel 1300. Letters “A”, “B”, “C”, and “D” are shown for reference among FIGS. 13-15.

CPS panel 1100 may comprise a greater area to accommodate PV cells compared to hCPS 1300, but a portion of PV cells in CPS panel 1100 may not receive substantial amounts of sunlight unless the sunlight is scattered by cloudy sky conditions, for example. On the other hand, hCPS panel 1300 may have substantially less area to accommodate PV cells 1366 compared to CPS panel 1100, for example, but hCPS panel 1300 may be useful to generate solar power in direct sun conditions for a number of reasons. To explain, hCPS panel 1300 may be oriented so that arrow 1308 points toward a southern direction (in the northern hemisphere, otherwise arrow points in a northern direction). With such an orientation, surfaces of hCPS panel 1300 may receive sunlight throughout the day as the sun moves across the sky from morning to evening. In the morning, for example, surfaces 1328 (e.g., a backside of surface 1316), 1326, and/or 1324 may receive sunlight. Midday sun may strike surfaces 1312, 1314, 1326, and/or 1324, but surfaces 1316 and/or 1328 may not receive light directly from the sun. In the evening, for example, surfaces 1316 (e.g., a backside of surface 1328), 1312, and/or 1314 may receive sunlight. Also, as the sun moves across the sky, the sunlight may strike the surfaces at various angles and/or be subsequently reflected into second surfaces to be further absorbed by PV cells disposed on the surfaces. hCPS panel 1300 may comprise an area to accommodate PV cells that is greater than the area of a footprint of hCPS panel 1300. For example, if surfaces 1312, 1314, 1316 . . . 1328 comprise 90-45-45 triangles, then hCPS panel 1300 may comprise an area to accommodate PV cells that is three times the area of a footprint of hCPS panel 1300, wherein a backside 1304 is not included in this calculation example (and an underside of sides 1314 and 1324 is not included). If backside 1304 does include PV cells (e.g., to receive scattered light) and is included in a calculation area, then hCPS panel 1300 may comprise an area to accommodate PV cells that is four times the area of a footprint of hCPS panel 1300. Thus, hCPS panel 1300 may provide advantages over a flat panel including avoiding use of costly mechanical sun-tracking devices, increasing available area to accommodate PV cells while maintaining a constant footprint, and/or providing PV cells positioned to receive non-absorbed light reflected from first-strike PV cells.

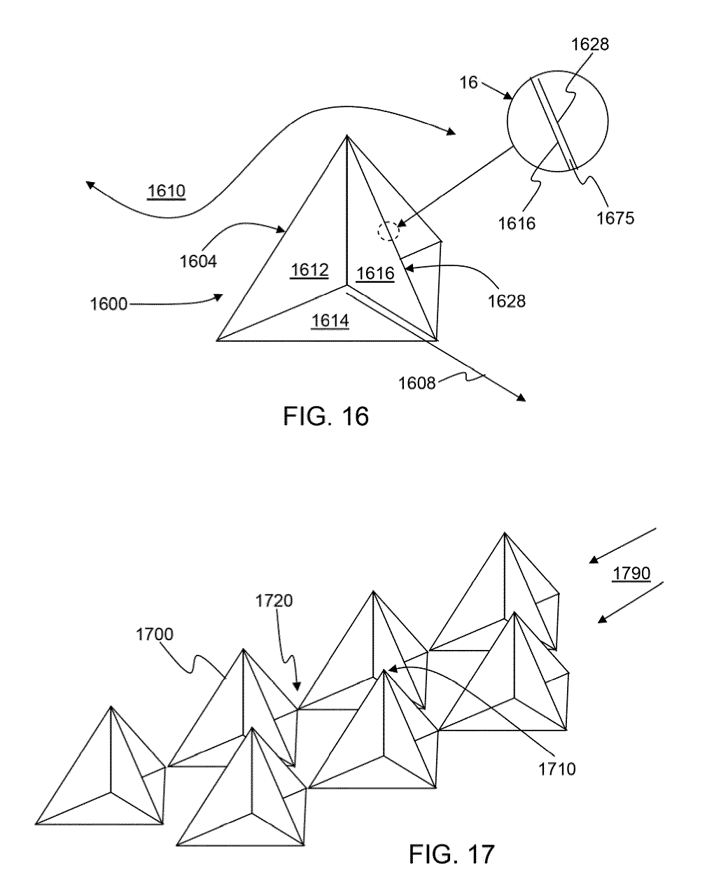

FIG. 16 shows a perspective view of a hCPS panel 1600 in a flow of air 1610, according to an embodiment. Three dimensional solar panels may lead to localized increases in wind speed as air is redirected up and over (and/or around) the solar panels. For example, referring to Bernoulli's Equation, air flow speed increases during a change in direction. Such increased air speed may help cool solar panels, which may tend to become relatively hot under clear sunny skies. PV cells may lose efficiency (e.g., approximately 10%) as the PV cells increase in temperature. Thus, increased air flow over and/or around three-dimensional solar panels may provide a cooling benefit to improve efficiency of PV cells.

In an implementation, hCPS panel 1600 may be oriented so that arrow 1608 is pointing southward so that direct light from the sun impinges on south facing sides (e.g., 1612, 1614, 1616, 1628 and others) of the panel 1600. A backside 1604, which may comprise a north-facing side if arrow 1608 is directed towards the south, may not receive direct sunlight and thus may be relatively cool compared to south facing sides receiving direct sunlight. In addition, a wind 1610 may impinge or flow along backside 1604 to help cool backside 1604 by removing heat transferred from south facing sides to backside 1604. Thus, backside 1604, though not contributing to solar power generation if there are no PV cells present on backside 1604, may provide cooling for panel 1600. Of course, in another implementation, PV cells may be present on backside 1604, which may contribute to solar power generation during cloudy sky conditions that produce scattered light that may reach PV cells on backside 1604. Presence of PV cells on backside 1604 need not preclude a cooling function for panel 1600 (backside 1604 may help cool panel 1600 with or without PV cells disposed on backside 1604). Of course, such cooling effects may apply to other three dimensional solar panels, such as panel 910 or 1100, for example.

In an implementation, side 1616 (and/or side 1628, which may comprise a backside of side 1628) may provide structural support for hCPS panel 1600. For example, side 1616 may provide buttressing between sides 1612 and/or sides 1614.

In a particular implementation, a space 1675 between sides 1616 and 1628 may provide space for airflow between sides 1616 and 1628, which may tend to become relatively hot under clear sunny skies. Space 1675 may formed by sides 1616 and 1628 spaced apart a few millimeters, a few centimeters, or a few inches for relatively large panels 1600, for example. Space 1675 may extend to backside 1604 and/or a base of panel 1600, which may comprise side 1614, for example. Of course, such a space may be present in other three dimensional solar panels, such as panel 910 or 1100, for example.

FIG. 17 shows a perspective view of multiple hCPS panels 1700, which may comprise groups of 3-sided pyramidal structures, according to an embodiment. Multiple panels 1700 may be arranged in rows and/or columns. Panels 1700 in consecutive rows (and/or columns) may be offset from one another so that apex regions 1710 of panels 1700 are aligned with low-point regions 1720 to reduce possible shadowing of sunlight 1790 (whether direct or scattered). Of course, multiple hCPS panels 1700 may extend by any number of panels 1700 in any direction. Of course, such details of three-dimensional solar panels, which may comprise hCPS panels, are merely examples, and claimed subject matter is not so limited.

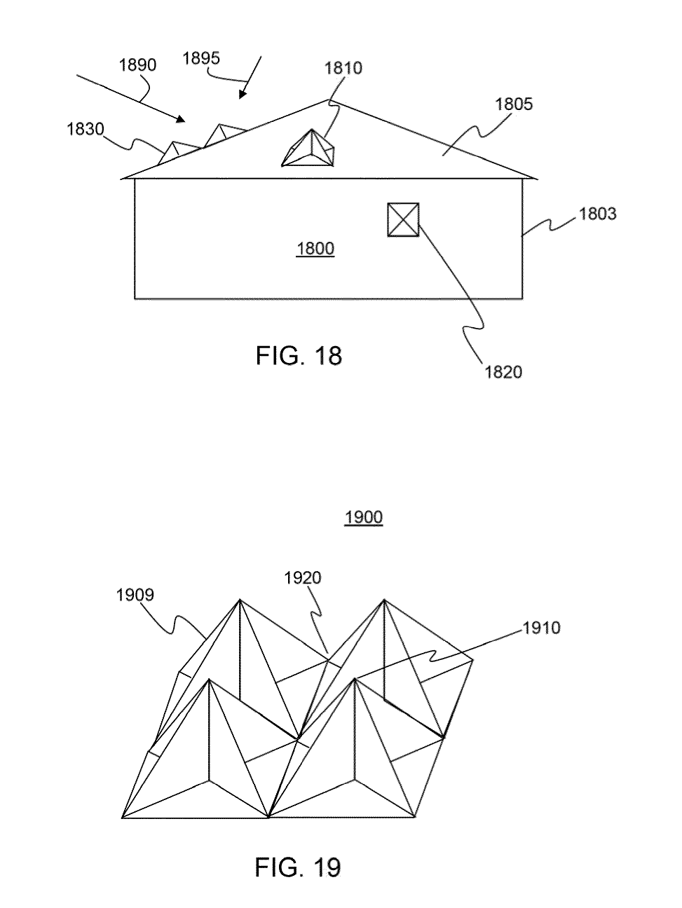

FIG. 18 shows a side view of various pyramidal structures on a building 1800, according to an embodiment. Of course, various pyramidal structures and/or three dimensional solar panels may be located on any structure, ground, vehicle, and so on. Roof 1805 of building (e.g., a house) 1800 may include various types of three-dimensional solar panels, according to an embodiment. In particular, in one implementation, one or more CPS panels 1810, 1820, or 1830 may be mounted on roof 1805 or wall 1803. Such CPS panels 1810 or 1820 may be similar to CPS panel 1100 shown in FIG. 11, for example. In another implementation, a hCPS panel and/or a panel similar to panel 910 (FIG. 9A) may replace CPS panels in FIG. 18 as an example wherein any type of panel (or any type of three dimensional solar panel) may be placed on a horizontal surface, a sloped surface (e.g., roof 1805) and/or a vertical surface (e.g., wall 1803). hCPS panels may be similar to hCPS panels 1300 or 1600 shown in FIGS. 13 and 16, for example. Sizes of CPS panels 1810, 1820, or 1830 (or hCPS panels) may comprise dimensions in the order of inches, feet, or yards, and claimed subject matter is not limited to any particular sizes of panels. Panels may be mounted to a roof and/or wall surface, for example, using brackets that may or may not provide a space or separation between a base of the panels and the mounting surface, though claimed subject matter is not so limited.

As discussed above, three-dimensional solar panels may provide a benefit in that such solar panels may include a relatively large surface area to receive scattered light, which may result from cloudy or rainy weather. For example, solar panels 1810, 1820, or 1830 may comprise surface area portions to receive light 1890 or light 1895 at the same time. On the other hand, to compare, a flat solar panel may occupy the same area of roof as the base of solar panel 1810, 1820, or 1830. A flat solar panel may also receive light 1890 and/or 1895. But surface area of such a flat solar panel may be substantially less than that of three-dimensional solar panels 1810, 1820, or 1830. Therefore, a flat solar panel may accommodate substantially less PV cell area compared to solar panel 1810, 1820, or 1830 for the same roof area, for example.

FIG. 19 shows a perspective view of multiple CPS panels 1909, which may comprise groups of 3-sided pyramidal structures, according to an embodiment. For example, CPS panels 1909 may be arranged in rows and/or columns in an array 1900. In an implementation (not shown in FIG. 19, but refer to FIG. 17), panels 1909 in consecutive rows (and/or columns) may be offset from one another so that apex regions 1910 of panels 1909 are aligned with low-point regions 1920 to reduce possible shadowing of sunlight (whether direct or scattered). Of course, array 1900 may extend by any number of panels 1909 in any direction.

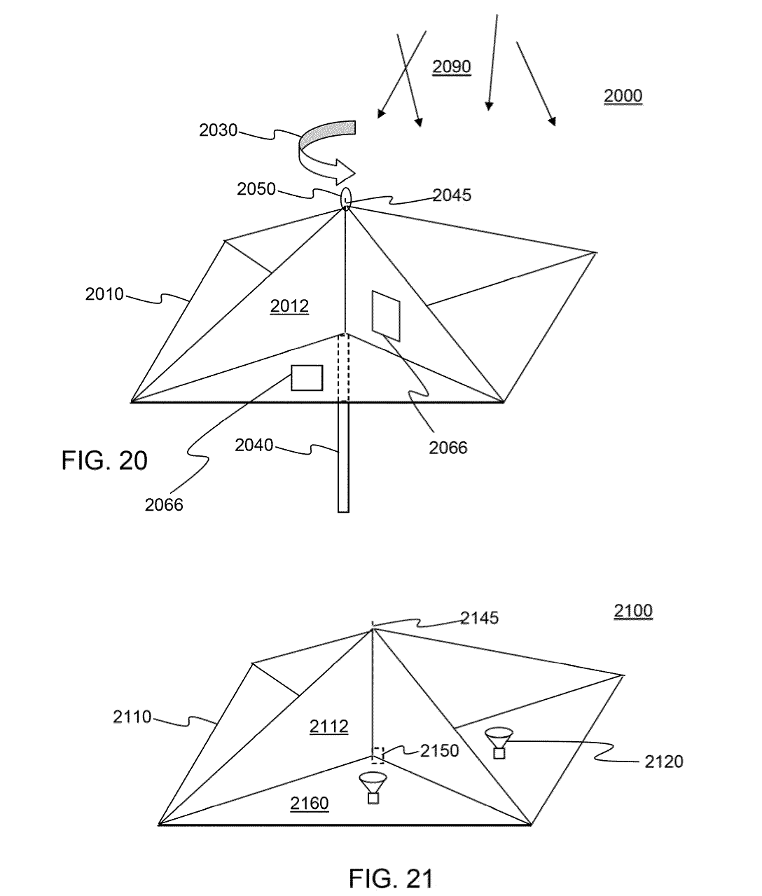

FIG. 20 shows a perspective view of a CPS panel 2010, which may comprise 3-sided pyramidal structures arranged adjacent to one another, according to an embodiment 2000. CPS panel 2010 may be rotatable about an axis 2045, as indicated by arrow 2030, for example. In one implementation, CPS panel 2010 may be mounted on a pole (e.g., rod, stick, etc.) or other element to allow CPS panel 2010 to have a rotational degree of freedom. In another implementation, CPS panel 2010 may include a hook or loop 2050 or other connection region from which to suspend or support CPS panel 2010. In one implementation, embodiment 2000 may comprise an ornament such as a yard ornament or a tree ornament, for example. Sides 2012 may comprise PV cells 2066, though any portion of any number of sides 2012 need not comprise PV cells.

FIG. 21 shows a perspective view of a CPS panel 2110, which may comprise 3-sided pyramidal structures arranged adjacent to one another that may include one or more lights 2120, according to an embodiment 2100. Lights 2120 may be powered by a battery 2150 that may be located under a base 2160 or any other location, for example. Battery 2150 may be charged by electricity generated by PV cells disposed on panel 2010 during times that light is present. If light is no longer present, and/or battery 2150 is charged, light 2120 may be illuminated, as described in further detail below. Embodiment 2100 may include a photosensor (not shown) to detect if light is present or not, for example. Rotational ability of embodiment 2000 may be combined with embodiment 2100 that includes one or more lights to result in an embodiment that may be used to generate electricity for external use and/or may be used as an ornament, for example.

FIG. 22 shows a perspective view of a CPS panel 2200, which may comprise 3-sided pyramidal structures arranged adjacent to one another, according to an embodiment. Panel 2200 may include openings 2245 to provide drainage of rain and/or melted snow, for example. Openings 2245 may comprise any number, any shape, and/or be located at any portion of panel 2200, such as in side 2214 and/or at least a portion of an edge thereof.

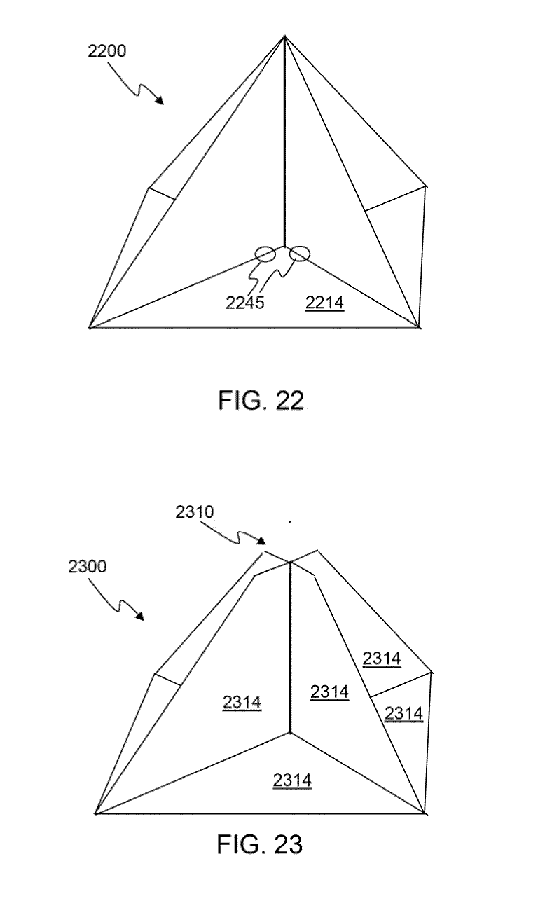

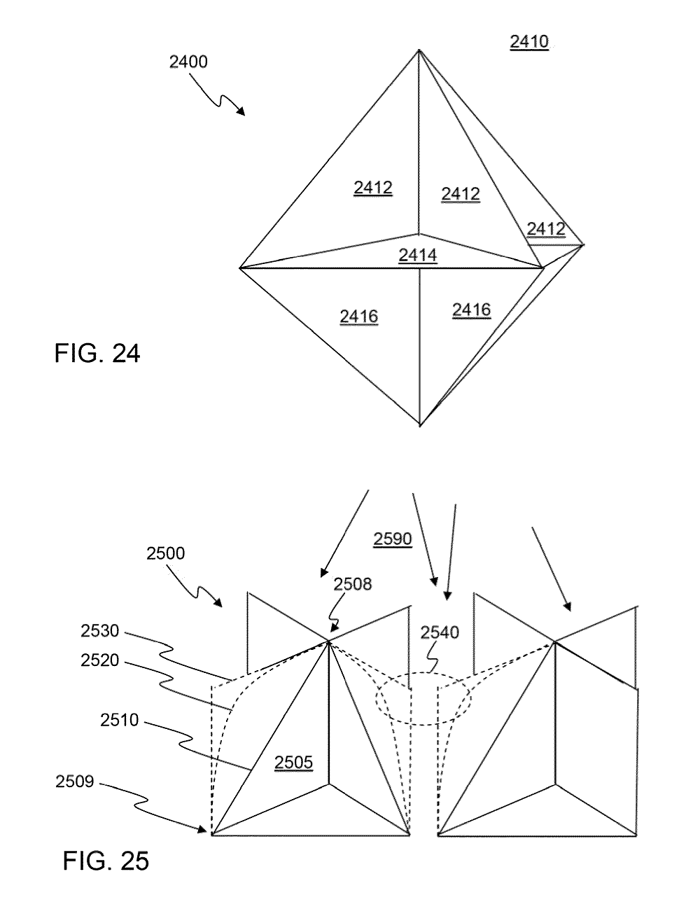

FIG. 23 shows a perspective view of a CPS panel 2300, which may comprise 3-sided pyramidal structures arranged adjacent to one another, according to an embodiment. Any portion of panel 2300 may comprise a truncated portion 2310. For example, any number of sides 2314 may comprise a truncated pyramid. In addition, embodiments described herein (e.g., embodiments 910, 1100, 1300, and/or 2400 (FIG. 24)) may be truncated at some portion. Claimed subject matter is not limited in this respect.

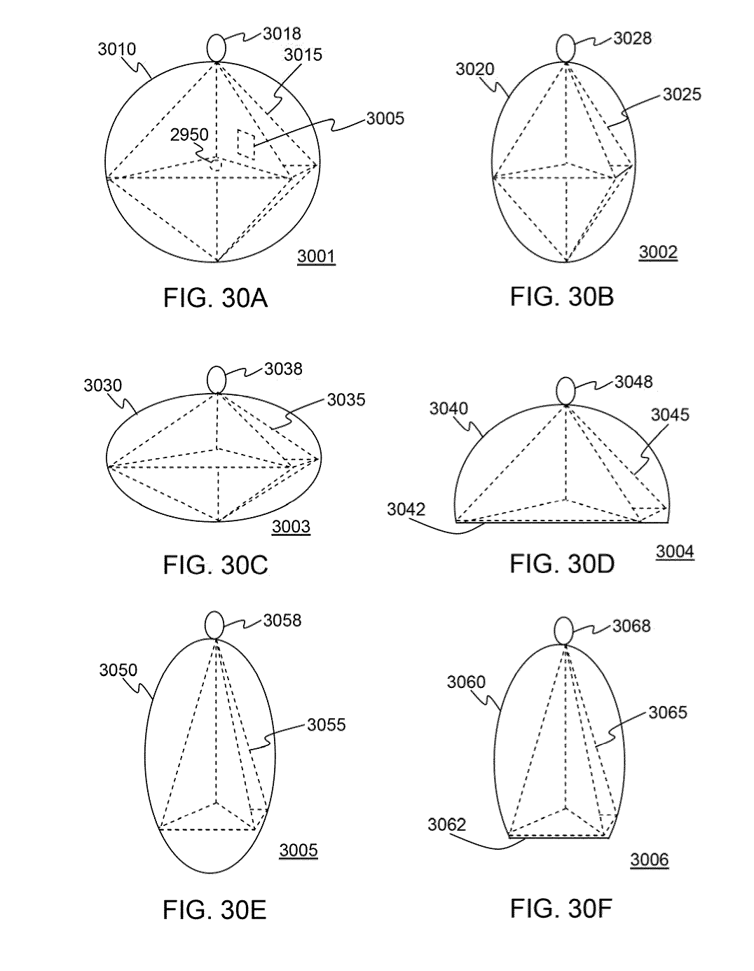

FIG. 24 shows a perspective view of two-ended CPS panel 2400, which may comprise 3-sided pyramidal structures arranged adjacent to one another, according to an embodiment 2410. Two-ended CPS panel 2400 may comprise multiple sides 2412 on one side of a base 2414 and multiple sides 2416 on another side of base 2414. Two-ended CPS panel 2400 may be applied as shown in FIGS. 20 and/or 21: with a rotational degree of freedom and/or with lights, for example. In one implementation, panel 2400 may comprise an ornament to be hung on a tree or as a garden ornament (e.g., see FIGS. 30A-30F), just to name a few examples. Two-ended CPS panel 2400 may provide a larger surface area than that of a CPS panel such as CPS panel 1100 shown in FIG. 11, for example. Any portion of any number of sides 2412, 2414, and/or 2416 may include PV cells, and claimed subject matter is not limited to any particular number of PV cells. In a particular implementation, two-ended CPS panel 2400 may be used as a RADAR corner reflector and include PV cells to generate electrical power. For example, ocean-going vehicles (e.g., boats, ships) may include a RADAR corner reflector. Including PV cells on surfaces of a RADAR corner reflector may provide solar power by receiving sunlight (direct and/or scattered) regardless of a direction or orientation (with respect to the vehicle or with respect to sun direction). This may be because PV cells included in any or all of eight quadrants of a panel 2400 may receive light respectively from any or all of eight quadrants of space (e.g., upper-north, upper-south, upper-east, upper-west, lower north, lower-south, lower-east, and/or lower-west). Vehicles that use a RADAR corner reflector may have access to limited electrical power to operate devices on-board. Thus, solar power generation may be useful. Of course, such details of three-dimensional solar panels are merely examples, and claimed subject matter is not so limited.

FIG. 25 shows a perspective view of two groups of 3-sided pyramidal structures arranged adjacent to one another, according to various embodiments. FIG. 25 may demonstrate that shapes of sides 2505 of a structure 2500 may affect how well-suited structure 2500 may be for grouping with other neighboring structures 2500. Structure 2500 may comprise a plurality of sides including side 2505, which is shown to have various possible edges 2510, 2520, or 2530, for example. Though only a few sides are shown with possible edges 2510, 2520, or 2530, other sides may include these edges as well. In one implementation, surface 2505 may comprise a triangular shape having an edge 2510 that slopes from an apex region 2508 to a base 2509. In another implementation, surface 2505 may comprise an edge 2520. In still another implementation, surface 2505 may comprise a square shape having an edge 2530. In an implementation where surface 2505 comprises a triangular shape with an edge 2510, an array or other group of multiple structures 2500 may be similar to that shown in FIG. 19. However, in an implementation where surface 2505 comprises a square shape with an edge 2530, multiple structures 2500 placed relatively close to one another may shadow one another at least partially. For example, region 2540 shows that edges 2520 or 2530 from adjacent structures 2500 may be relatively close to one another, which may result in undesirable amounts of light 2590, whether scattered or direct, being blocked. In contrast, edge 2510, though providing less area to accommodate PV cells, may be well-suited for allowing structures 2500 to be placed relatively close to one another, as in FIG. 19, for example.

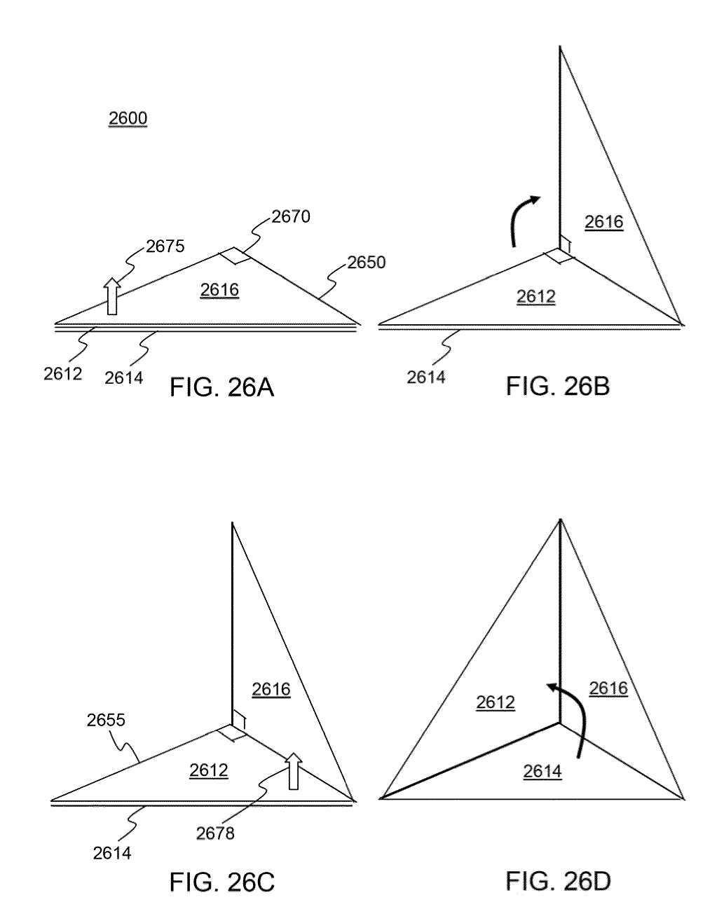

FIGS. 26A-26D show a perspective view of a 3-sided pyramidal solar panel structure 2600 being formed, according to an embodiment. Structure 2600 may comprise sides 2612, 2614, and/or 2616, which may include PV cells on all or part of their surfaces. In one implementation, PV cells may be located on one or both sides of sides 2612, 2614, and/or 2616. In one implementation, sides 2612, 2614, and/or 2616 may comprise right triangles, as indicated by right-angle symbol 2670, for example. At least portions of sides 2612, 2614, and/or 2616 may be connected to one another by a hinge, flexible material, and/or other device to allow one surface to be rotated with respect to another surface. In a particular implementation, for example, at least a portion of side 2616 may be hinge-wise connected to at least a portion of side 2612 along edge 2650. A pulling force 2675, for example, applied to a portion of side 2616 may lift-rotate side 2616 to a position shown in FIG. 26B, thus exposing side 2612 (and PV cells that may be located on side 2612, for example). In a particular implementation, for example, side 2612 may be hinge-wise connected to side 2614 along edge 2655. A pulling force 2678, for example, applied to a portion of side 2612 may lift-rotate side 2612 to a position shown in FIG. 26D, thus exposing side 2614 (and PV cells that may be located on side 2614, for example). Such assembly (e.g., unfolding) of sides 2612, 2614, and 2616 may result in a 3-sided pyramidal solar panel, shown in FIG. 26D, which may include PV cells on an inward side, an outward side, or both. Such assembly, for example, may be similar to solar panel 910 shown in FIG. 9A.

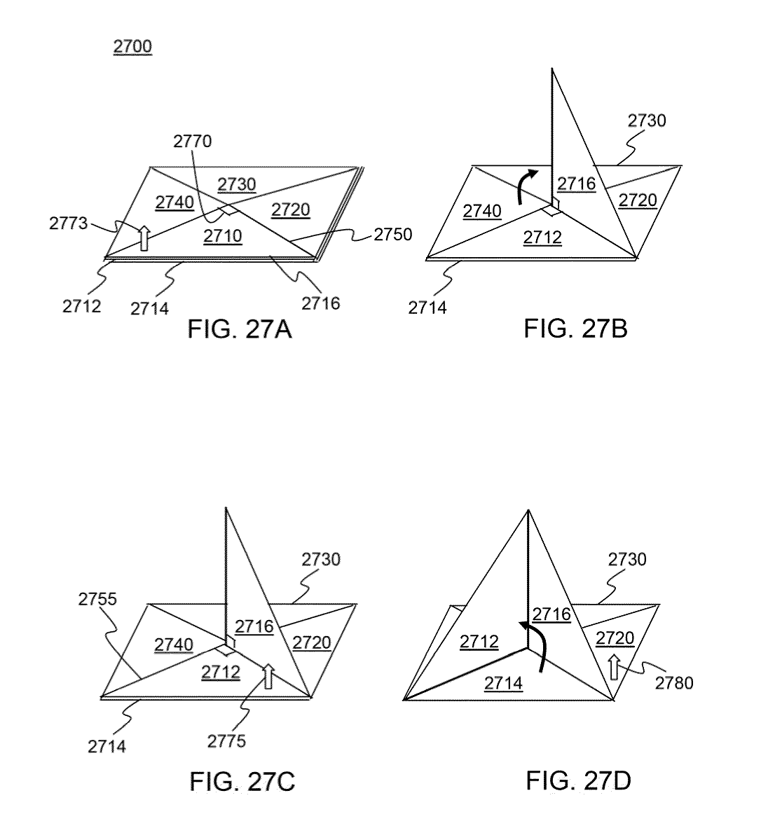

FIGS. 27A-27D show a perspective view of multiple 3-sided pyramidal solar panel structures 2700 being formed, according to an embodiment. Structure 2700 may comprise portions 2710, 2720, 2730, and/or 2740. Such portions may comprise three layers of sides. For example, portion 2710 may comprise sides 2716 (exposed in FIG. 27A), 2714, and/or 2712. Any or all of these sides may include PV cells, for example, on all or part of their surfaces. In one implementation, PV cells may be located on one or both sides of sides 2712, 2714, and/or 2716. In one implementation, sides 2712, 2714, and/or 2716 may comprise right triangles, as indicated by right-angle symbol 2770, for example. At least portions of sides 2712, 2714, and/or 2716 may be connected to one another by a hinge, flexible material, and/or other device to allow one surface to be rotated with respect to another surface. In a particular implementation, for example, at least a portion of side 2716 may be hinge-wise connected to at least a portion of side 2712 along edge 2750. A pulling force 2773, for example, applied to a portion of side 2716 may lift-rotate side 2716 to a position shown in FIG. 27B, thus exposing side 2712 (and PV cells that may be located on side 2712, for example). In a particular implementation, for example, at least a portion of side 2712 may be hinge-wise connected to at least a portion of side 2714 along edge 2755. A pulling force 2775, for example, applied to a portion of side 2712 may lift-rotate side 2712 to a position shown in FIG. 27D, thus exposing side 2714 (and PV cells that may be located on side 2714, for example). Such assembly (e.g., unfolding) of sides 2712, 2714, and 2716 may result in a 3-sided pyramidal solar panel, shown in FIG. 26D, which may include PV cells on an inward side, an outward side, or both. In addition, other portions 2720, 2730, and/or 2740 may be assembled into 3-sided pyramidal solar panels similar to that shown for portion 2710 in FIGS. 27A-27D, for example. For example, a pulling force 2780 applied to a portion of a side of 2720 may lift-rotate the side to a (e.g., upright) position, thus exposing a side below. In an implementation where portions 2710, 2720, 2730, and/or 2740 are assembled into 3-sided pyramidal solar panels, a resulting structure may comprise a CPS panel, such as CPS 1100 shown in FIG. 11, for example. In an implementation where portion 2710 and either portion 2720 or portion 2740 are assembled into 3-sided pyramidal solar panels, a resulting structure may comprise a hCPS panel, such as hCPS panel 1300 shown in FIG. 13, for example.

In one implementation, structure 2700 may comprise a square base on which sides (e.g., sides 2712-2740) shown in FIG. 27A are connected by at least portions of their edges. In another implementation, a structure similar to structure 2700 may comprise a half a square base on which sides 2712, 2714, 2716, and/or sides in portions 2720, for example, are connected by at least portions of their edges. Such implementations may be assembled into three dimensional solar panels comprising, for example, embodiments 1100 and/or 1300, respectively. Structure 2700, which may be relatively flat and be assembled into a three dimensional solar panel, may be useful for shipping, carrying, and/or storing in a flat state and assembling “in the field”, for example.

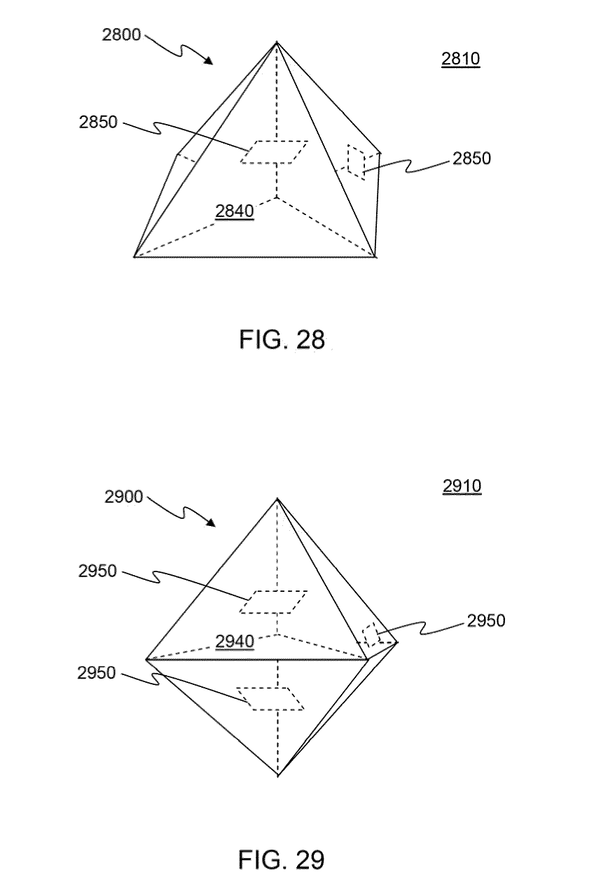

FIG. 28 shows a perspective view of a CPS panel 2800, which may comprise multiple 3-sided pyramidal structures arranged adjacent to one another and covered by a clear material 2840, according to an embodiment 2810. “Glare spots” 2850 are drawn to assist in visualizing a presence of material 2840, for example. Material 2840 may comprise a protective layer to cover CPS panel 2800. For example, material 2840 may protect CPS panel 2800 from weather, such as rain, ultraviolet sunlight, and so on. Material 2840 may also strengthen CPS panel 2800. For example, a material 2840 on CPS panel 2800 may allow CPS panel 2800 to be handled (e.g., carried, stored, shipped, packaged, and so on) while reducing danger of damage to the panel. A strengthened CPS panel 2800 may be desirable if CPS panel 2800 comprises an ornament or garden feature, for example. Sizes (e.g., dimensions) of panel 2800 may be in the order of centimeters, decimeters, meters, and so on, though claimed subject matter is not so limited.

Material 2840 may be clear to avoid blocking light to PV cells on sides of CPS panel 2800. In another implementation, material 2840 may be colored and/or translucent for aesthetic purposes, though a portion of incoming light may be blocked and/or absorbed by material 2840. Material 2840 may cover CPS panel 2800 on all sides, or one or more sides (e.g., a bottom side) may be exposed and/or not be covered by material 2840, for example. Material 2840 may comprise a pyramidal shape to cover CPS panel 2800. Glare spots 2850 indicate that material 2840 may comprise a single plane to cover the three sides of the 3-sided inverted pyramid structure of CPS panel 2800, for example. In another embodiment, however, material 2840 may be shaped to conform to panel 2800. In one implementation, material 2840 may comprise a sealed and/or flexible enclosure to hold a vacuum. If such material contains a vacuum and solar panel 2800, the flexible material may at least partially conform to geometry of the panel 2800, for example.

CPS panel 2800 covered in protective material 2840 may be replaced by a hCPS panel. In addition, a hook or other type of hanging mechanism may be added to embodiment 2810 so that panel 2800 may be hung as an ornament or for another application, for example. Panel 2800 may also be supported by a pole, such as pole 2040 shown in FIG. 20.

FIG. 29 shows a perspective view of a two-ended CPS panel 2900, which may comprise multiple 3-sided pyramidal structures arranged adjacent to one another and covered by a clear material 2940, according to an embodiment 2910. “Glare spots” 2950 are drawn to assist in visualizing a presence of material 2940, for example. Material 2940 may comprise a protective layer to cover panel 2900. For example, material 2940 may protect panel 2900 from weather, such as rain, ultraviolet sunlight, and so on. Material 2940 may also strengthen panel 2900. For example, a material 2940 on panel 2900 may allow panel 2900 to be handled (e.g., carried, stored, shipped, packaged, and so on) while reducing danger of damage to the panel. Of course, such a material may also provide additional strength to panel 2900 during operation (e.g., “in the field”). A strengthened CPS panel 2900 may be desirable if panel 2900 comprises an ornament or garden feature, for example, which may be subjected to a greater amount of handling compared to a panel operating to generate utility-type electricity. Sizes (e.g., dimensions) of panel 2800 may be in the order of centimeters, decimeters, meters, and so on.

Material 2940 may be clear to avoid blocking light to PV cells on sides of panel 2900. In another implementation, material 2940 may be colored and/or translucent (e.g., frosted) for aesthetic purposes, though a portion of incoming light may be blocked and/or absorbed by material 2940. Material 2940 may cover panel 2900 on all sides, or one or more sides (e.g., a bottom side) may be exposed and/or not covered by material 2940, for example. Material 2940 may comprise a two-ended pyramidal shape to cover panel 2900. Glare spots 2950 indicate that material 2940 may comprise a single plane to cover the three sides of a quadrant of the 3-sided inverted pyramid structure of panel 2900, for example.

FIGS. 30A-30D show a perspective view of various three dimensional solar panels at least partially enclosed in a covering, according to an embodiment. Three dimensional solar panels may be used in ornamental applications, for example. Such a panel is herein called a three dimensional solar panel (3dSP) ornament. PV cells (e.g., multi-crystalline, bluish color, though claimed subject matter is not so limited) may be aesthetically pleasing so that PV cells may contribute to an attractive appearance of a 3dSP ornament, for example. Three dimensional solar panels included in an ornament may be used to generate electricity to power one or more light sources (e.g., light emitting diodes (LEDs)) included in an ornament. Three dimensional solar panels may provide an advantage in ornamental applications (among other applications, such as those described above, for example) by their ability to receive light from many directions and/or their increased surface area to accommodate PV cells compared to flat solar panels. Thus, relatively dim light, which may be present indoors, for example, may be received by three dimensional solar panels having a relatively greater area of PV cells facing multiple directions, compared to flat solar panels. Such dim light, for example, may comprise scattered light, light from one or more artificial sources (e.g., light bulbs, fluorescent light tubes, and so on), and/or from direct and/or scattered sunlight from windows. Three dimensional solar panels may provide another advantage in ornamental applications in that a 3dSP ornament may receive substantial amounts of light regardless of a position or orientation of the 3dSP ornament. For example, a 3dSP ornament may be hung via a hook using string so that the ornament may rotate if disturbed, for example. Even if inadvertently rotated, a 3dPV ornament may still receive a relatively large amount of light to generate power for an on-board light (or lights), for example. A 3dSP ornament may also be placed without a need for careful positioning because the ornament may receive light from many directions.

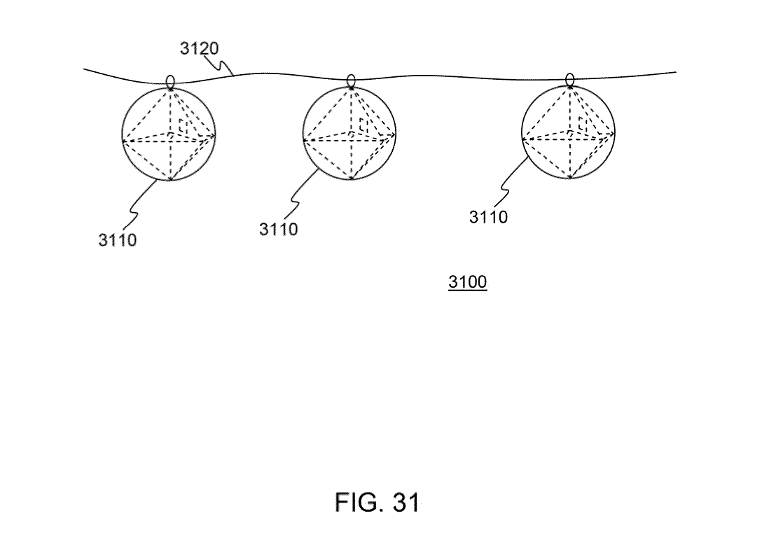

In one embodiment, multiple 3dSP ornaments may be connected together via a cord or line. In another embodiment, multiple 3dSP ornaments may be connected together via a cord or line, which need not comprise a conductive wire. An example embodiment 3100 is shown in FIG. 31. For example, a chain of 3dSP ornaments 3110 may comprise multiple ornaments connected together via a cord or line 3120 and not include an electrically-conducting wire connecting the 3dSP ornaments to one another and/or to a power source: Electrical power need not be carried to 3dSP ornaments, which may be self-powered using on board PV cells. Thus, an implementation may comprise a plurality of light ornaments (e.g., one or more lights included on-board the ornaments) physically connected to one another without including conductive wires between individual light ornaments. For example, a plurality of light ornaments may be physically connected to one another by a decorative linked chain exclusive of any electrically-conductive wires, since such conductive wires along the chain may be unattractive or otherwise undesirable. For another example, a plurality of light ornaments may be physically connected to one another by relatively slender and/or clear cord (e.g., fishing line) exclusive of any electrically-conductive wires, since such conductive wires along the cord may be unattractive or otherwise undesirable. Accordingly, line 3120 to physically connect 3dSP ornaments need not include any electrically conducting wires, for example.

In embodiments shown in FIGS. 30A-30F, 3dSP ornaments may comprise a three dimensional solar panel, such as a CPS panel, and need not include a covering as shown in the figures. As mentioned above, a covering may protect PV cells included in the ornament, but such a covering may be optional. A covering may comprise a transparent, translucent, opaque, and/or colored material such as plastic or glass. Different portions of a covering may comprise different materials and/or have different properties (e.g., one portion may be clear and/or another portion may be translucent). A covering may comprise a single sealed piece, two hemispherical portions, or two or more other-shaped portions, just to name a few examples. Such portions may be glued or otherwise bonded to one another or mechanically (e.g., screwed, bolted, and so on) attached to one another to provide a sealed interface (e.g., seam). In another implementation, covering portions may be overlapped, and may or may not be sealed (e.g., glued and/or caulked). For example, one portion may comprise an edge region to slip over or under an edge region of another portion. In a particular implementation, a top portion (e.g., such as a semi-spherical shaped portion) may comprise an edge to slip over an edge of a lower portion. Thus, rain or other weather components may be shed from an ornament by gravity without dripping into an inside portion of the ornament, for example. A covering need not be spherical or an ellipsoid, but may comprise any shape, including shapes with planar portions, for example. A covering may comprise any thickness of material, in the order of millimeters or thicker, for example. A covering may comprise an anti-reflection (AR) coating to improve light transmittance. In a particular implementation, a covering may be frosted to obscure a view of inside features of an ornament and/or to provide a soft, blurred lighting of one or more lights included in the ornament. (Of course, such details of a covering are merely examples, and claimed subject matter is not so limited.

In embodiments shown in FIGS. 30A-30F, three dimensional solar panels may include PV cells on all or a portion of one or more sides of the solar panels, whether or not shown explicitly in the figures. For example, three dimensional solar panels depicted in the figures may comprise a material and/or framework on which PV cells are mounted. Thus, for example, three dimensional solar panels comprise multiple sides that may include portions that are “bare” without PV cells and/or portions that are covered with PV cells.

In embodiments shown in FIGS. 30A-30F, three dimensional solar panels may include one or more hooks or other mechanisms from which a 3dSP ornament may be hung. Though a loop is shown in the figures, a loop need not be present, a loop may be replaced by one or more other devices, and/or a loop (or other device) may be located on any portion(s) of a 3dSP ornament (e.g., not limited to a region where an apex of a three dimensional solar panel may be located).

In FIG. 30A, a 3dSP ornament embodiment 3001 may comprise a three dimensional solar panel 3015 including PV cells 3005, a hook 3018, a covering 3010, and/or one or more light sources 2950 (e.g., LEDs), which may be located on the three dimensional solar 3015 panel and/or covering 3010, for example. One or more light sources may be located as desired for aesthetic purposes, for example. Light produced from light sources may reflect from one or more sides of three dimensional solar panel 3015 to produce desirable lighting, for example. Three dimensional solar panel 3015 may comprise a two-ended CPS panel, as described above, for example. Though not shown, a 3dSP ornament may include a battery and/or conductors to store and/or carry electricity between PV cells and one or more lights. In one implementation, a 3dSP ornament may also include a PV cell or photocell to detect whether light is present, and/or a switch to selectively connect one or more lights to a battery. For example, during light conditions (e.g., daylight or room lights on), one or more lights 2950 may be switched off and/or not receive power from a battery. During light conditions, a battery may be charged from power generated by PV cells. During relatively dark conditions (e.g., night time or room lights off), one or more lights 2950 may be switched on to receive power from a battery. In another implementation, a 3dSP ornament may include circuitry to determine whether light is present by detecting an amount of electricity generated (if any) by PV cells. In such an implementation, a separate photocell, as described above, need not be used. Circuitry may include a switch to selectively connect one or more lights to a battery. Such circuitry and/or battery may be located in any portion of a 3dSP ornament, and/or may be placed to be relatively not visible for aesthetic reasons, for example. An underside 3042 or 3062 shown in FIGS. 30D and 30F may include circuitry and/or a battery, for example.

FIG. 30B shows a 3dSP ornament embodiment 3002 that may comprise a three dimensional solar panel 3025 including PV cells, a hook 3028, a covering 3020, and/or one or more lights, which may be located on the three dimensional solar panel 3025 and/or covering 3020, for example. Embodiment 3002 may be similar to embodiment 3001 except, for example, that relative dimensions may be different to provide a different shape.

FIG. 30C shows a 3dSP ornament embodiment 3003 that may comprise a three dimensional solar panel 3035 including PV cells, a hook 3038, a covering 3030, and/or one or more lights, which may be located on the three dimensional solar panel 3035 and/or covering 3030, for example. Embodiment 3003 may be similar to embodiment 3001 except, for example, that relative dimensions may be different to provide a different shape.

FIG. 30D shows a 3dSP ornament embodiment 3004 that may comprise a three dimensional solar panel 3045 including PV cells, a hook 3048, a covering 3040, and/or one or more lights, which may be located on the three dimensional solar panel 3045 and/or covering 3040, for example. Embodiment 3004 may be similar to embodiment 3001 except, for example, that relative dimensions may be different to provide a different shape and three dimensional solar panel 3045 may comprise a CPS panel, as described above, for example.

FIG. 30E shows a 3dSP ornament embodiment 3005 that may comprise a three dimensional solar panel 3055 including PV cells, a hook 3058, a covering 3050, and/or one or more lights, which may be located on the three dimensional solar panel 3055 and/or covering 3050, for example. Embodiment 3005 may be similar to embodiment 3001 or 3004 except, for example, that relative dimensions may be different to provide a different shape and three dimensional solar panel 3055 may comprise a CPS panel, as described above, for example.

FIG. 30F shows a 3dSP ornament embodiment 3006 that may comprise a three dimensional solar panel 3065 including PV cells, a hook 3068, a covering 3060, and/or one or more lights, which may be located on the three dimensional solar panel 3065 and/or covering 3060, for example. Embodiment 3006 may be similar to embodiment 3001 or 3004 except, for example, that relative dimensions may be different to provide a different shape and three dimensional solar panel 3065 may comprise a CPS panel, as described above, for example. Of course, such details of three-dimensional solar panels included in ornaments are merely examples, and claimed subject matter is not so limited.

Reference throughout this specification to “one embodiment” or “an embodiment” means that a particular feature, structure, or characteristic described in connection with an embodiment is included in at least one embodiment of claimed subject matter. Thus, appearances of phrases such as “in one embodiment” or “an embodiment” in various places throughout this specification are not necessarily all referring to the same embodiment. Furthermore, particular features, structures, or characteristics may be combined in one or more embodiments.

One skilled in the art will realize that a virtually unlimited number of variations to the above descriptions is possible, and that the examples and the accompanying figures are merely to illustrate one or more particular implementations.

The terms, “and,” “and/or,” and “or” as used herein may include a variety of meanings that also is expected to depend at least in part upon the context in which such terms are used. Typically, “or” as well as “and/or” if used to associate a list, such as A, B or C, is intended to mean A, B, and C, here used in the inclusive sense, as well as A, B or C, here used in the exclusive sense. In addition, the term “one or more” as used herein may be used to describe any feature, structure, or characteristic in the singular or may be used to describe some combination of features, structures, or characteristics. Though, it should be noted that this is merely an illustrative example and claimed subject matter is not limited to this example.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. A three-dimensional solar panel comprising:
two or more pyramid structures arranged adjacent to one another to form a compound pyramid shape, wherein said two or more pyramid structures include photovoltaic cells on at least a portion of inward surfaces of said two or more pyramid structures.

2. The three-dimensional solar panel of claim 1, wherein said pyramid structures comprise 3-sided pyramid structures.

3. The three-dimensional solar panel of claim 2, wherein individual said 3-sided pyramid structures comprise three substantially 90-45-45 triangle-shaped portions that include PV cells.

4. The three-dimensional solar panel of claim 2, wherein said two or more 3-sided pyramid structures comprise a group of four 3-sided pyramid structures, and wherein an exposed surface area of said four 3-sided pyramid structures is approximately three times the area of a footprint of combined said four 3-sided pyramid structures.

5. The three-dimensional solar panel of claim 1, wherein said two or more pyramid structures arranged adjacent to one another are arranged back-to-back.

6. The three-dimensional solar panel of claim 1, further comprising one or more light sources.

7. The three-dimensional solar panel of claim 1, wherein said pyramidal surfaces comprise one or more truncated triangular surfaces.

8. The three-dimensional solar panel of claim 1, further comprising another two or more 3-sided pyramidal surfaces, wherein said two or more 3-sided pyramidal surfaces and said another two or more 3-sided pyramidal surfaces are substantially symmetrical of one another about a base that is common to both said two or more 3-sided pyramidal surfaces and said another two or more 3-sided pyramidal surfaces.

9. The three-dimensional solar panel of claim 1, further comprising a transparent covering to at least partially enclose said three-dimensional solar panel.

10. A solar power generating device comprising:
a first set of three mutually perpendicular photovoltaic (PV) surfaces arranged to receive light from at least a first quadrant of sky; and
a second set of three mutually perpendicular PV surfaces arranged to receive light from at least a second quadrant of the sky, wherein said first and said second quadrants are exclusive of one another.

11. The solar power generating device of claim 10, further comprising:
a third set of three mutually perpendicular PV surfaces arranged to receive light from at least a third quadrant of the sky; and
a fourth set of three mutually perpendicular PV surfaces arranged to receive light from at least a fourth quadrant of the sky, wherein said third and said fourth quadrants are exclusive of one another.

12. The solar power generating device of claim 10, wherein said PV surfaces of said first set and said second set comprise 90-45-45 triangles.

13. The solar power generating device of claim 10, wherein said first set of three mutually perpendicular PV surfaces comprises:
inside edges that are substantially mutually perpendicular to one another; or
outside edges that form a 60-60-60 equilateral triangle.

14. A three-dimensional solar ornament, comprising:
a three-dimensional solar panel to generate electricity; and
one or more light sources to use said electricity, wherein said three-dimensional solar panel includes two or more photovoltaic surfaces to respectively receive scattered light from two or more different directions.

15. The three-dimensional solar ornament of claim 14, wherein said three-dimensional solar panel comprises a compound pyramidal solar panel.

16. The three-dimensional solar ornament of claim 14, further comprising a battery to store said electricity and to provide said electricity to said one or more light sources.

17. The three-dimensional solar ornament of claim 14, further comprising:
additional said three-dimensional solar ornaments physically connected to one another and not electrically connected to one another.

18. The three-dimensional solar ornament of claim 14, further comprising:
a covering to at least partially enclose said three-dimensional solar panel.

19. The three-dimensional solar ornament of claim 14, further comprising:
circuitry to selectively switch said one or more light sources on or off.

20. The three-dimensional solar ornament of claim 19, wherein said selectively switching is based, at least in part, on detecting an amount of said electricity generated by said three-dimensional solar panel.
